(19) United States
(12) Patent Application Publication
(10) Pub. No.: US 2022/0181210 A1
(43) Pub. Date: Jun. 9, 2022

(54) METHOD FOR REMOVING A BAR OF ONE OR MORE DEVICES USING SUPPORTING PLATES

(71) Applicant: The Regents of the University of California, Oakland, CA (US)

(72) Inventors: Takeshi Kamikawa, Santa Barbara, CA (US); Srinivas Gandrothula, Santa Barbara, CA (US); Masahiro Araki, Santa Barbara, CA (US)

(73) Assignee: The Regents of the University of California, Oakland, CA (US)

(21) Appl. No.: 17/434,687

(22) PCT Filed: Mar. 12, 2020
(86) PCT No.: PCT/US20/22430

§ 371 Date: Aug. 27, 2021

Related U.S. Application Data
(60) Provisional application No. 62/817,216, filed on Mar. 12, 2019.

(51) Int. Cl. H01L 21/78; H01L 23/00

(52) U.S. Cl. CPC H01L 21/7813; H01L 24/83; H01L 24/94; H01L 2924/3512; H01L 2924/12042; H01L 2924/13091; H01L 2924/37001; H01L 2924/12041

(57) ABSTRACT

A method for removing devices from a substrate using a supporting plate. One or more bars comprised of semiconductor layers are formed on a substrate, and one or more device structures are formed on the bars. At least one supporting plate is bonded to the bars, and stress is applied to the supporting plate to remove the bars from the substrate. The supporting plate is used to divide the bars into one or more device units after the bars are removed from the substrate, wherein the device units are packaged and arranged into one or more modules. The supporting plate may also be used to make a cleavage facet for one or more of the device structures after the bars are removed from the substrate.

### CROSS REFERENCE TO RELATED APPLICATIONS

This application claims the benefit under 35 U.S.C. Section 119(e) of the following co-pending and commonly-assigned application:

U.S. Provisional Application Ser. No. 62/817,216, filed on Mar. 12, 2019, by Takeshi Kamikawa, Srinivas Gandrothula and Masahiro Araki, entitled “METHOD FOR REMOVING A BAR OF ONE OR MORE DEVICES USING SUPPORTING PLATES,” attorneys' docket number G&C 30794.0724USP1 (UC 2019-416-1);

which application is incorporated by reference herein.

This application is related to the following co-pending and commonly-assigned applications:

U.S. Utility patent application Ser. No. 16/608,071, filed on Oct. 24, 2019, by Takeshi Kamikawa, Srinivas Gandrothula, Hongjian Li and Daniel A. Cohen, entitled “METHOD OF REMOVING A SUBSTRATE,” attorney's docket number 30794.0653USWO (UC 2017-621-1), which application claims the benefit under 35 U.S.C. Section 365(c) of co-pending and commonly-assigned PCT International Patent Application No. PCT/US18/31393, filed on May 7, 2018, by Takeshi Kamikawa, Srinivas Gandrothula, Hongjian Li and Daniel A. Cohen, entitled “METHOD OF REMOVING A SUBSTRATE,” attorney's docket number 30794.0653WOU1 (UC 2017-621-2), which application claims the benefit under 35 U.S.C. Section 119(e) of co-pending and commonly-assigned U.S. Provisional Patent Application No. 62/502,205, filed on May 5, 2017, by Takeshi Kamikawa, Srinivas Gandrothula, Hongjian Li and Daniel A. Cohen, entitled “METHOD OF REMOVING A SUBSTRATE,” attorney's docket number 30794.0653USP1 (UC 2017-621-1);

U.S. Utility patent application Ser. No. 16/642,298, filed on Feb. 20, 2020, by Takeshi Kamikawa, Srinivas Gandrothula and Hongjian Li, entitled “METHOD OF REMOVING A SUBSTRATE WITH A CLEAVING TECHNIQUE,” attorney's docket number 30794.0659USWO (UC 2018-086-2), which application claims the benefit under 35 U.S.C. Section 365(c) of co-pending and commonly-assigned PCT International Patent Application No. PCT/US18/51375, filed on Sep. 17, 2018, by Takeshi Kamikawa, Srinivas Gandrothula and Hongjian Li, entitled “METHOD OF REMOVING A SUBSTRATE WITH A CLEAVING TECHNIQUE,” attorney's docket number 30794.0659WOU1 (UC 2018-086-2), which application claims the benefit under 35 U.S.C. Section 119(e) of co-pending and commonly-assigned U.S. Provisional Patent Application No. 62/559,378, filed on Sep. 15, 2017, by Takeshi Kamikawa, Srinivas Gandrothula and Hongjian Li, entitled “METHOD OF REMOVING A SUBSTRATE WITH A CLEAVING TECHNIQUE,” attorney's docket number 30794.0659USP1 (UC 2018-086-1);

PCT International Patent Application No. PCT/US19/25187, filed on Apr. 1, 2019, by Takeshi Kamikawa, Srinivas Gandrothula and Hongjian Li, entitled “METHOD OF FABRICATING NONPOLAR AND SEMIPOLAR DEVICES USING EPITAXIAL LATERAL OVERGROWTH,” attorney's docket number 30794.0680WOU1 (UC 2018-427-2), which application claims the benefit under 35 U.S.C. Section 119(e) of co-pending and commonly-assigned U.S. Provisional Patent Application Ser. No. 62/650,487, filed on Mar. 30, 2018, by Takeshi Kamikawa, Srinivas Gandrothula, and Hongjian Li, entitled “METHOD OF FABRICATING NONPOLAR AND SEMIPOLAR DEVICES BY USING LATERAL OVERGROWTH,” attorney docket number G&C 30794.0680USP1 (UC 2018-427-1);

PCT International Patent Application No. PCT/US19/32936, filed on May 17, 2019, by Takeshi Kamikawa and Srinivas Gandrothula, entitled “METHOD FOR DIVIDING A BAR OF ONE OR MORE DEVICES,” attorney's docket number 30794.0681WOU1 (UC 2018-605-2), which application claims the benefit under 35 U.S.C. Section 119(e) of co-pending and commonly-assigned U.S. Provisional Application Ser. No. 62/672,913, filed on May 17, 2018, by Takeshi Kamikawa and Srinivas Gandrothula, entitled “METHOD FOR DIVIDING A BAR OF ONE OR MORE DEVICES,” attorneys' docket number G&C 30794.0681USP1 (UC 2018-605-1);

PCT International Patent Application No. PCT/US19/34686, filed on May 30, 2019, by Srinivas Gandrothula and Takeshi Kamikawa, entitled “METHOD OF REMOVING SEMICONDUCTING LAYERS FROM A SEMICONDUCTING SUBSTRATE,” attorney's docket number 30794.0682WOU1 (UC 2018-614-2), which application claims the benefit under 35 U.S.C. Section 119(e) of co-pending and commonly-assigned U.S. Provisional Application Ser. No. 62/677,833, filed on May 30, 2018, by Srinivas Gandrothula and Takeshi Kamikawa, entitled “METHOD OF REMOVING SEMICONDUCTING LAYERS FROM A SEMICONDUCTING SUBSTRATE,” attorneys' docket number G&C 30794.0682USP1 (UC 2018-614-1);

PCT International Patent Application No. PCT/US19/59086, filed on Oct. 31, 2019, by Takeshi Kamikawa and Srinivas Gandrothula, entitled “METHOD OF OBTAINING A SMOOTH SURFACE WITH EPITAXIAL LATERAL OVERGROWTH,” attorney's docket number 30794.0693WOU1 (UC 2019-166-2), which application claims the benefit under 35 U.S.C. Section 119(e) of co-pending and commonly-assigned U.S. Provisional Application Ser. No. 62/753,225, filed on Oct. 31, 2018, by Takeshi Kamikawa and Srinivas Gandrothula, entitled “METHOD OF OBTAINING A SMOOTH SURFACE WITH EPITAXIAL LATERAL OVERGROWTH,” attorneys' docket number G&C 30794.0693USP1 (UC 2019-166-1);

PCT International Patent Application No. PCT/US20/13934, filed on Jan. 16, 2020, by Takeshi Kamikawa, Srinivas Gandrothula and Masahiro Araki, entitled “METHOD FOR REMOVAL OF DEVICES USING A TRENCH,” attorney's docket number 30794.0713WOU1 (UC 2019-398-2), which application claims the benefit under 35 U.S.C. Section 119(e) of co-pending and commonly-assigned U.S. Provisional Application Ser. No. 62/793,253, filed on Jan. 16, 2019, by Takeshi Kamikawa, Srinivas Gandrothula and Masahiro Araki, entitled “METHOD FOR REMOVAL OF DEVICES USING A TRENCH,” attorneys' docket number G&C 30794.0713USP1 (UC 2019-398-1); and

PCT International Patent Application No. PCT/US20/20647, filed on Mar. 2, 2020, by Takeshi Kamikawa and Srinivas Gandrothula, entitled “METHOD FOR FLATTENING A SURFACE ON AN EPITAXIAL LATERAL GROWTH LAYER,” attorney's docket number 30794.0720WOU1 (UC 2019-409-2), which application claims the benefit under 35 U.S.C. Section 119(e) of co-pending and commonly-assigned U.S. Provisional Application Ser. No. 62/812,453, filed on Mar. 1, 2019, by Takeshi Kamikawa and Srinivas Gandrothula, entitled “METHOD FOR FLATTENING A SURFACE ON AN EPITAXIAL LATERAL GROWTH LAYER,” attorneys' docket number G&C 30794.0720USP1 (UC 2019-409-1);

all of which applications are incorporated by reference herein.

### BACKGROUND OF THE INVENTION

### 1. Field of the Invention

This invention relates to a method for removing a bar of one or more devices using supporting plates.

### 2. Description of the Related Art

Currently, various methods are used for removing devices from a foreign or hetero-substrate, such as wet etching, laser ablation, sacrificial layers, etc. However, such methods may not be appropriate for homo-substrates.

For example, some device manufacturers have used III-nitride substrates, such as GaN substrates, to produce III-nitride-based devices, such as laser diodes (LDs) and light-emitting diodes (LEDs), for lighting, optical storage, electronics devices and sensors etc. However, the cost of GaN substrates has prevented their wider use in fabricating III-nitride-based devices.

Moreover, it is easier to remove a foreign or hetero-substrate from epitaxial layers at a hetero-interface using laser ablation or other techniques. However, III-nitride-based semiconductor layers deposited on GaN substrates lack a hetero-interface, which makes it difficult to remove the GaN substrates from the TI-nitride-based semiconductor layers.

Consequently, there is a need for a technique that removes III-nitride substrates or layers from III-nitride-based semiconductor layers in an easy manner.

In one previous technique, a GaN layer is spalled by a stressor layer of metal under tensile strain. See, e.g., Applied Physics Express 6 (2013) 112301 and U.S. Pat. No. 8,450,184, both of which are incorporated by reference herein. Specifically, this technique uses spalling in the middle of the GaN layer.

However, surface morphology on a spalling plane is rough and this technique cannot be controlled at the spalling position. Moreover, this removal method may damage the semiconductor layers due to excess bending in the layer that is being removed, which may result in cracks in unintended directions.

Thus, it is necessary to reduce any such damages and determine the removing position. When it comes to a mass-production, it is important to determine the removing position, because varying the removing position may reduce the yield of the mass-production.

Another conventional technique is the use of photoelectrochemical (PEC) etching of sacrificial layers to remove device structures from GaN substrates, but this takes a long time and involves several complicated processes.

Thus, there is a need in the art for improved methods of removing III-nitride substrates from III-nitride-based semiconductor layers, especially where GaN thin films are grown on GaN substrates.

### SUMMARY OF THE INVENTION

To overcome the limitations in the prior art described above, and to overcome other limitations that will become apparent upon reading and understanding this specification, the present invention discloses a method for removing a bar of one or more device using supporting plates.

Specifically, this invention performs the following steps:

Step 1: Fabricate bars comprised of devices on a substrate.

Step 2: Determine a removing position for the bars.

Step 3: Bond supporting plates to the bars.

Step 4: Apply stress to the supporting plates in a vertical direction to the bars to remove the bars at the removing position.

Step 5: Implement device processes after the removal of the bars.

Step 6: Mount the devices with the supporting plates to a stem and stage of a module.

This invention has many advantages in terms of removing bars of devices from the homo- and hetero-substrates. This invention can be adapted to many kinds of opto-electronic devices.

### BRIEF DESCRIPTION OF THE DRAWINGS

Referring now to the drawings in which like reference numbers represent corresponding parts throughout:

FIGS. 1(a), 1(b), 1(c), 1(d), 1(e), 1(f), 1(g) and 1(h) illustrate the structure of the devices and the process flow for fabricating the devices.

FIG. 2 shows the basic configuration of the device structure.

FIGS. 3(a) and 3(b) illustrate the direction of the growth restrict mask on the substrate.

FIGS. 4(a), 4(b), 4(c), 4(d), 4(e), 4(f), 4(g), 4(h), 4(i), 4(j), 4(k), 4(l), 4(m) and 4(n) illustrate a second case for the structure of the devices and the process flow for fabricating the devices.

FIGS. 5(a), 5(b) and 5(c) describe a method for manufacturing bars without using an epitaxial lateral overgrowth (ELO) technique.

FIGS. 6(a), 6(b) and 6(c) illustrate how to determine a removing position for the bars.

FIG. 7 is a scanning electron microscope (SEM) image showing the edge of the growth restrict mask.

FIG. 8 explains how to bond bars and supporting plates.

FIGS. 9(a) and 9(b) illustrate bonding to a conventional LED device structure and a conventional LD device structure, using a p-electrode configuration.

FIGS. 10(a) and 10(b) illustrate bonding to a conventional LED device structure.

FIGS. 11(a), 11(b) and 11(c) illustrate the use of holding-type supporting plates, wherein the supporting plate is a fin.

FIGS. 12(a), 12(b), 12(c), 12(d), 12(e) and 12(f) illustrate the use of fins and a holding plate or film on the substrate with bars for bonding.

FIGS. 13(a), 13(b), 13(c), 13(d), 13(e) and 13(f) illustrate the use of the holding plate or film and fins bonded to the bars and substrate.

FIGS. 14(a), 14(b) and 14(c) illustrate how n-electrodes are disposed at a separate area of the bar.

FIG. 15 illustrates the use of a dividing support region formed at periodic lengths according to device length.

FIG. 16 illustrates the use of the dividing support region and trench, as well as other types of dividing support regions.

FIGS. 17(a) and 17(b) illustrate two types of supporting plates, without or with a depressed portion.

FIGS. 18(a), 18(b), 18(c) and 18(d) illustrate a first method of dividing the bar.

FIGS. 19(a), 19(b), 19(c) and 19(d) illustrate a second method of dividing the bar wherein the supporting plate has depressed regions.

FIGS. 20(a) and 20(b) illustrate a third method of dividing the bar that is a variation of the second method of dividing the bar without a depressed region.

FIGS. 21(a), 21(b) and 21(c) illustrate a fourth method of dividing the bar that uses a dry etch method to cleave and/or divide the bar.

FIGS. 21(d) and 21(e) illustrate variation on the fourth method.

FIGS. 22(a) and 22(b) illustrate a fifth method of dividing the bar that bends the bar and supporting plate, which results in the bar being cleaved and/or divided.

FIGS. 23(a) and 23(b) illustrate how stress is applied to bend the bar into a concave shape.

FIGS. 24(a), 24(b) and 24(c) illustrate a sixth method of dividing the bar wherein stress is applied to the bar using the differences in the thermal expansion co-efficient between the bar and supporting plate.

FIG. 25 shows SEM images that illustrate how the edge of the bar has a variety of shapes depending on a plane of the substrate.

FIG. 26 illustrates a method of coating facets that is performed on a number of divided chips at the same time in an easy manner.

FIGS. 27(a) and 27(b) illustrate how the coating can be formed as a wrapping region at the edge of the bar.

FIGS. 28(a) and 28(b) illustrate how aging tests are conducted.

FIG. 29 illustrates how a laser diode is packaged.

FIG. 30 illustrates how devices can be mounted directly in a package.

FIG. 31 illustrates how devices are handled and mounted into a package.

FIG. 32 illustrates the structure of a polymer film.

FIG. 33 shows SEM images that illustrate the use of various mis-cut orientations of an m-plane substrate.

FIG. 34 shows SEM images that illustrate the use of various mis-cut orientations of semi-polar plane substrates.

FIG. 35 shows SEM images that illustrate the use of various mis-cut orientations of non-polar, semi-polar, and non-polar plane substrates.

FIGS. 36(a) and 36(b) illustrate some options in the way of removing the bar.

FIGS. 37(a) and 37(b) illustrate how etching may be used for making laser facets.

FIGS. 38(a) and 38(b) illustrate dividing support regions, depressed regions, etched mirror regions, and coating layers.

FIGS. 39(a) and 39(b) illustrate the fabrication of a vertical cavity surface emitting laser.

FIG. 40 is a schematic of a vertical cavity surface emitting laser (VCSEL) with a supporting plate.

FIGS. 41(a), 41(b), 41(c) and 41(d) illustrate how the supporting plate is attached to the bar of an LED.

FIGS. 42(a) and 42(b) illustrate the device after the removal of the bar, wherein there is an etched N-polar surface at the back side of the bar.

FIG. 43 is a flowchart that illustrates a method for removing a bar comprised of one or more devices from a substrate by bonding supporting plates to the bars.

### DETAILED DESCRIPTION OF THE INVENTION

In the following description of the preferred embodiment, reference is made to a specific embodiment in which the invention may be practiced. It is to be understood that other embodiments may be utilized and structural changes may be made without departing from the scope of the present invention.

Overview

The present invention describes a method for removing a bar comprised of one or more devices from a substrate by bonding supporting plates to the bars. Specifically, this invention performs the following steps:

Step 1: Fabricate one or more bars comprised of one or more devices on a substrate.

There are several methods of fabricating the bars. Moreover, this step may include various processes to fabricate the devices on the bars.

Step 2: Determine a removing position for each of the bars.

Step 3: Bond one or more supporting plates to the bars.

Step 4: Apply stress to the supporting plates in a vertical direction to the bar (i.e., orthogonal to the surface of the bar), which removes the bars at the removing positions.

Step 5: Implement additional device processes, if necessary, after removal of the bars, such as disposing an n-electrode on the back side of the bars, making facets for laser diode devices, and so on. These processes are not always necessary because every process may be completed before the removal of the bars.

Step 6: Mount the devices with the supporting plates to a stem and stage of a module. If the supporting plates have a high thermal conductivity, then the supporting plates can be mounted directly to the stem and stage of the module. On the other hand, if thermal conductivity of the supporting plates is low, then a side of the devices can contact the stem and stage of the module in order to maintain a high thermal conductivity.

Removing the bars using the above steps provides a number of advantages when fabricating devices:
Thin layer devices having a wide width in an area in contact with the substrate can be removed with this method.
This method can remove a variety of sizes of devices. For example, very small laser diode devices can be fabricated, which is very important.
Supporting plates help apply stress to the removing position.
Avoids breaking the bars after the removal. Specifically, bonding and contacting the supporting plates to the bars prevents the bars from breaking.
It is easy to handle the bars after removal. This allows the bars to be mounted to a stage, as well as perform facet coating and n-electrode deposition after removal. Moreover, it avoids damage to the bars by touching a collet chuck, etc.
Bonding the supporting plates completes the process of junction-down mounting at the same time. The present invention can be implemented to mount many bars to a sub-mount with the junction down at the same time. This can reduce processing time and allows some common processes to be performed.
Using this invention, the supporting plates can be bonded to bars even if the height of the bars is different in each bar.
The yield of the bonding process can be increased by the invention.
Supporting plates help divide bars into devices and help form facets on the devices by cleaving quickly and easily.
Supporting plates make it possible to implement a reliability check with the devices in an unsealed condition in an easy and low cost manner.

Therefore, this invention has many kinds of advantages in terms of removing bars from homo-substrates and hetero-substrates, such as gallium arsenide, indium phosphide, gallium antimonide, etc. Moreover, the removed bars can be easily and quickly processed after the removal because the supporting plates prevent the bars from breaking during processing. Bonding the supporting plates to the bars can assist injunction-down mounting.

The present invention can be used to grow and fabricate an number of different devices, including light-emitting diodes (LEDs), laser diodes (LDs), vertical cavity surface emitting devices (VCSELs), Schottky barrier diodes (SBDs), metal-oxide-semiconductor field-effect-transistors (MOSFETs), or other devices.

Process Steps

The steps of the present invention are described in more detail below:

Step 1: Fabricate a Bar Comprised of One or More Devices on a Substrate.

Several methods may be used in fabricating a bar comprised of one or more devices on a substrate.

Case 1:

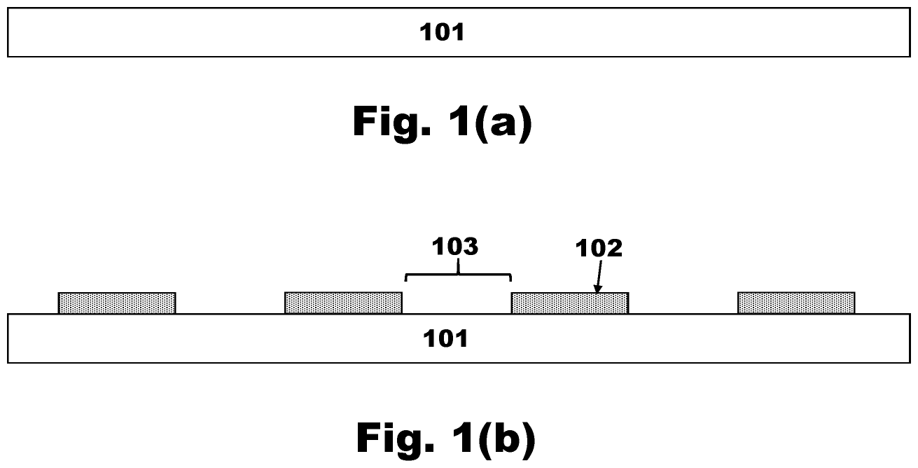

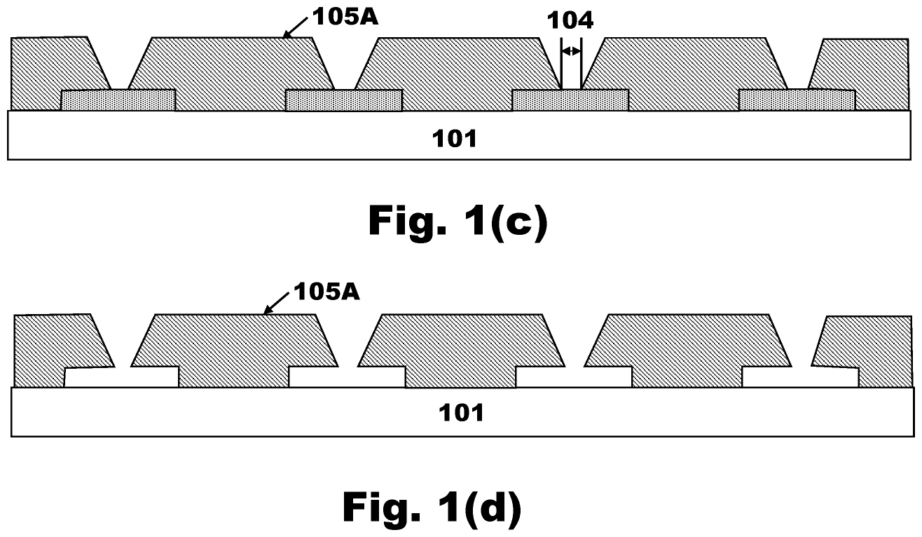

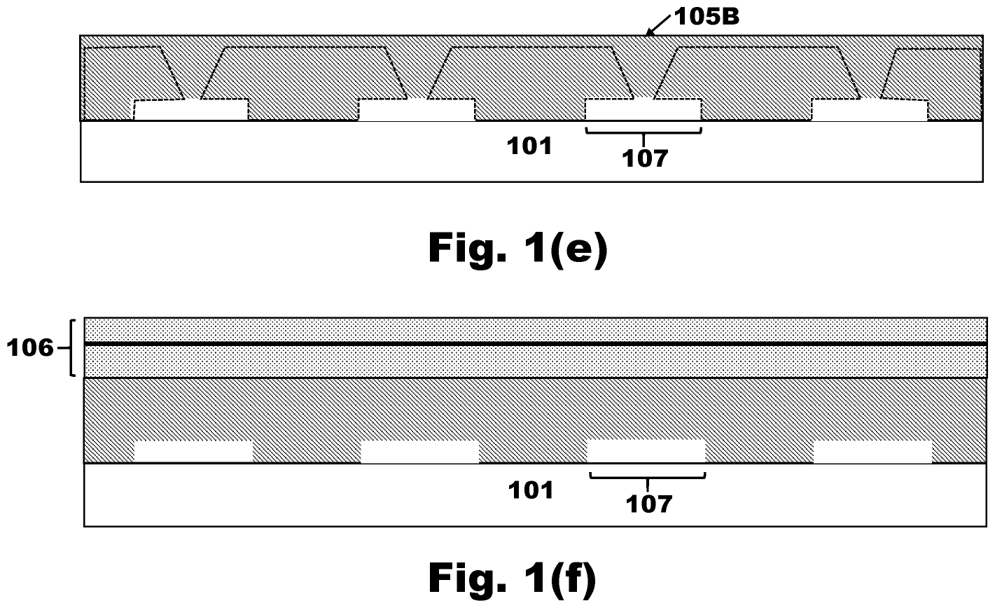

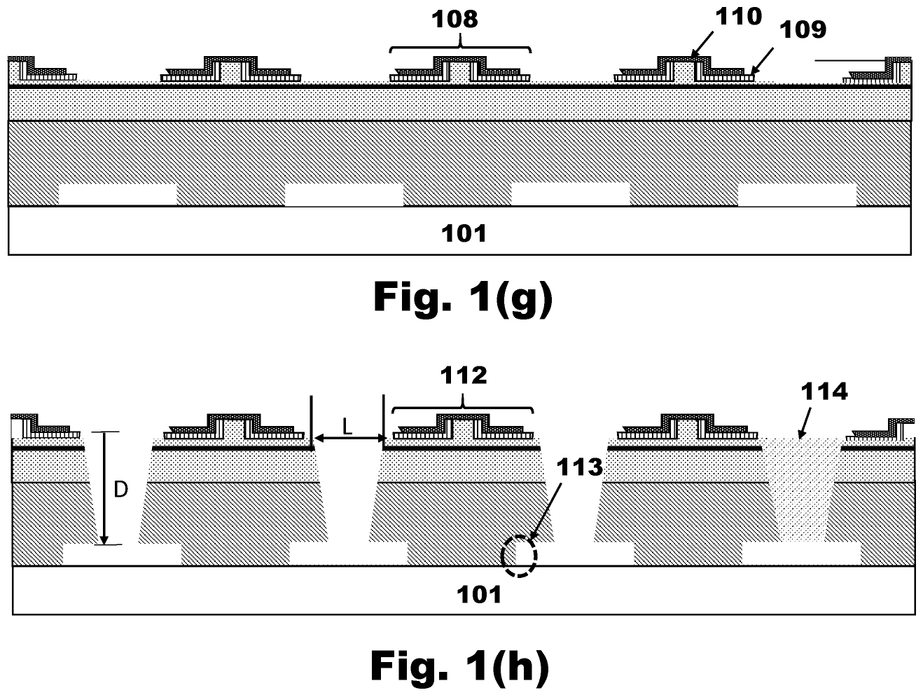

FIGS. 1(a)-1(h), FIG. 2 and FIGS. 3(a)-3(b) illustrate a first case for the structure of the devices and the process flow for fabricating the devices, according to the present invention.

FIGS. 1(a)-1(h) illustrate a process for fabricating a bar comprised of one or more devices on a substrate 101, which may comprise a III-nitride substrate, a template substrate 101 with a GaN layer or a hetero substrate 101, a growth restrict mask 102, opening areas 103, no-growth regions 104, III-nitride ELO layers 105A, III-nitride regrowth layers 105B, III-nitride device layers 106, void regions 107, ridge structures 108, current blocking layers 109, p-type electrodes 110, polymers film 111, separated bars 112, breaking points 113, and etched regions 114.

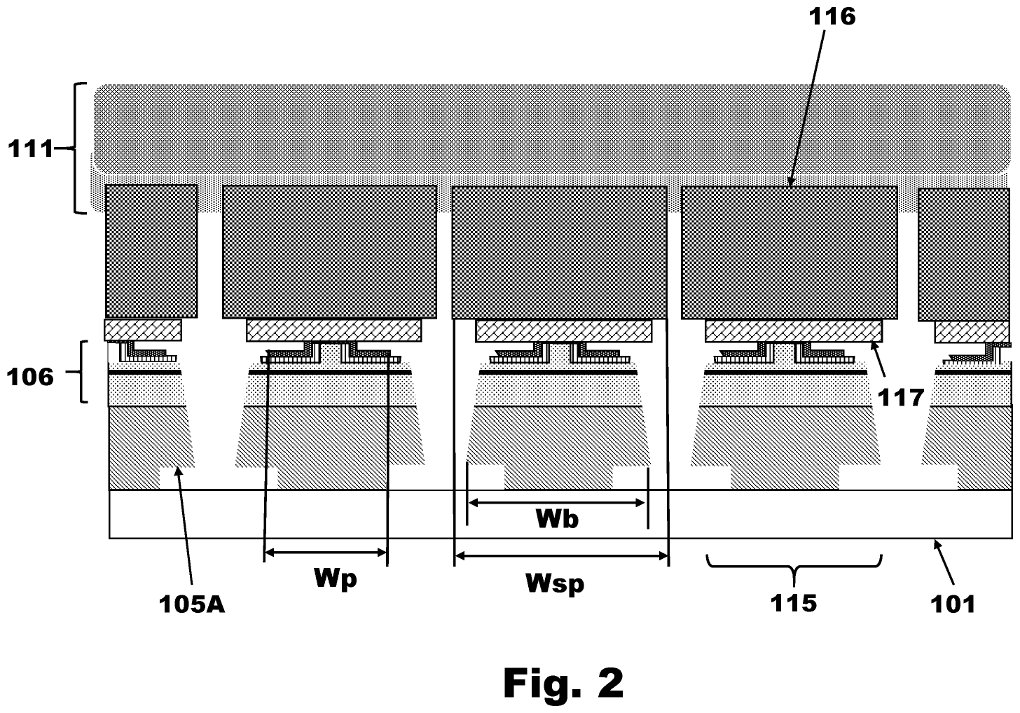

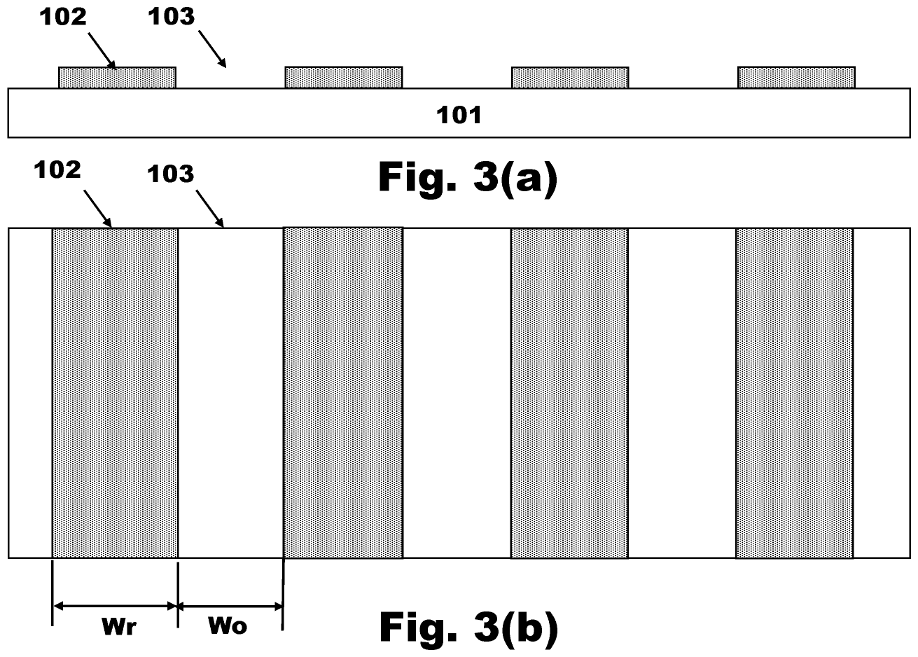

The basic configuration of the resulting structure is shown in FIG. 2. The resulting structure comprises a bar 115 comprised of one or more devices formed by the substrate 101, III-nitride ELO layers 105A, III-nitride regrowth layers 105B, and III-nitride device layers 106, wherein the bars 115 are separated from each other. Each bar 115 is bonded to a supporting plate 116 using a bonding metal 117, wherein the supporting plate 116 and a polymer film 111 are used to remove the bar 115 from the substrate 101, as described in more detail below.

A more detailed description of the steps used by the present invention in fabricating the bar 115 of devices is provided below:

Process 1: Depositing the growth restrict mask 102 on the substrate 101 with the remaining surface exposed by striped opening areas 103 in the growth restrict mask 102, as shown in FIG. 1(b). FIGS. 3(a) and 3(b) illustrate the direction of the growth restrict mask 102 on the substrate 101. In alternative embodiments, the growth restrict mask 102 may be formed on a c-plane substrate 101 or an m-plane substrate 101.

Process 2: Growing the III-nitride ELO layers 105A on the substrate 101 using the growth restrict mask 102, such that the growth extends in a direction parallel to the striped opening areas 103 of the growth restrict mask 102, and the I-nitride ELO layers 105A do not coalesce, as shown in FIG. 1(c).

Process 3: Removing the substrate 101 with the III-nitride ELO layers 105A from the MOCVD reactor, wherein at least a part of the growth restrict mask 102 is removed by dry or wet etching method with an etchant such as hydrofluoride (HF) or buffered HF (BHF), as shown in FIG. 1(d).

Process 4: Growing the regrowth layers 105B on the III-nitride ELO layers 105A in order to form void regions 107 and flatten the surface of the layers, as shown in FIG. 1(e). In the case of a wider width of the growth restrict mask 102, there is a possibility of many cracks occurring due to the differences in thermal expansion co-efficiency between the ELO III-nitride layers 105A and growth restrict mask 102. The void regions 107 can prevent cracks from occurring in the ELO III-nitride layers 105A by reducing stress in the layers.

Process 5: Growing the III-nitride device layers 106 on the regrowth layers 105B, as shown in FIG. 1(f). When the surface is rough, the surface may be polished by chemical mechanical polishing (CMP), etc., which makes the in-plane distribution of layer thicknesses decrease with the growth of the III-nitride device layers 106.

Process 6: Fabricating the device at the flat surface region by conventional methods, wherein the ridge structure, p-electrode, pad-electrode etc., are disposed on the 11n-nitride device layers 106, which comprise island-like III-nitride semiconductor layers, at pre-determined positions, as shown in FIG. 1(g).

Process 7: Etching at least a part of the I-nitride device layers 106, the regrowth layers 105B, and the III-nitride ELO layers 105A, by a conventional dry etch method, as shown in etching region 114 in FIG. 1(h).

By doing this, bars 115 of devices can be obtained. Also, the breaking point 113, which is a removing position 113, can be obtained utilizing the growth restrict mask 102, as shown in FIG. 1(h).

Case 2:

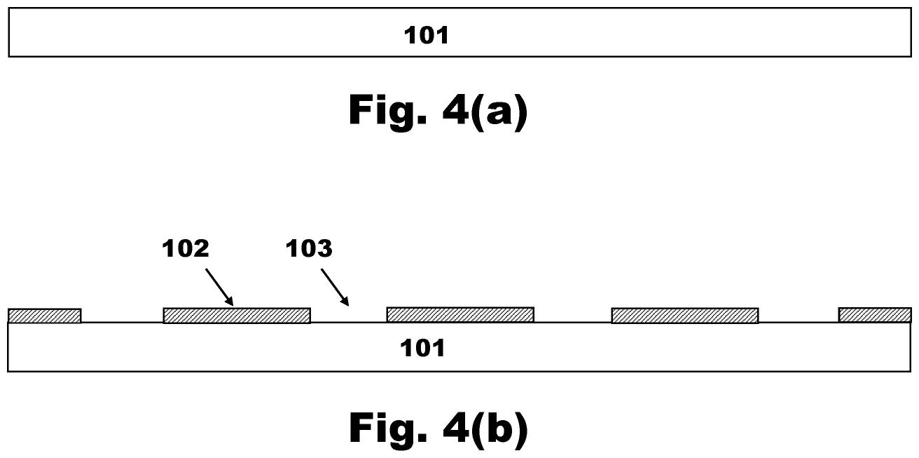

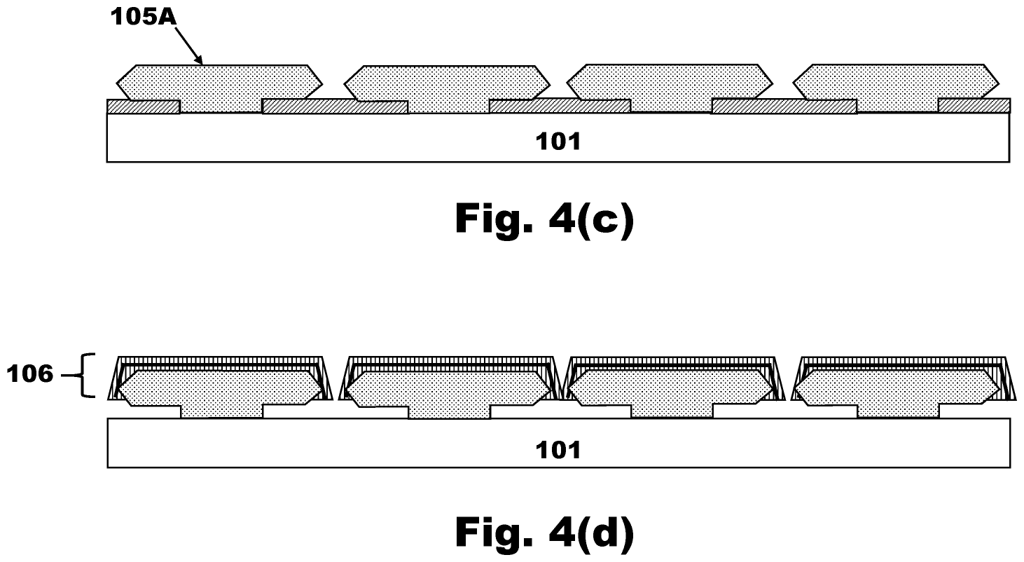

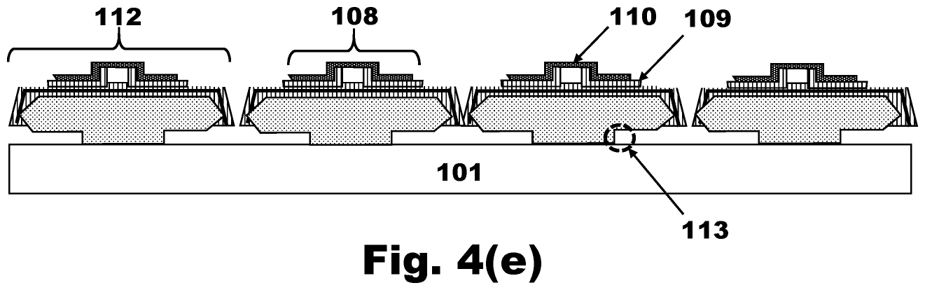

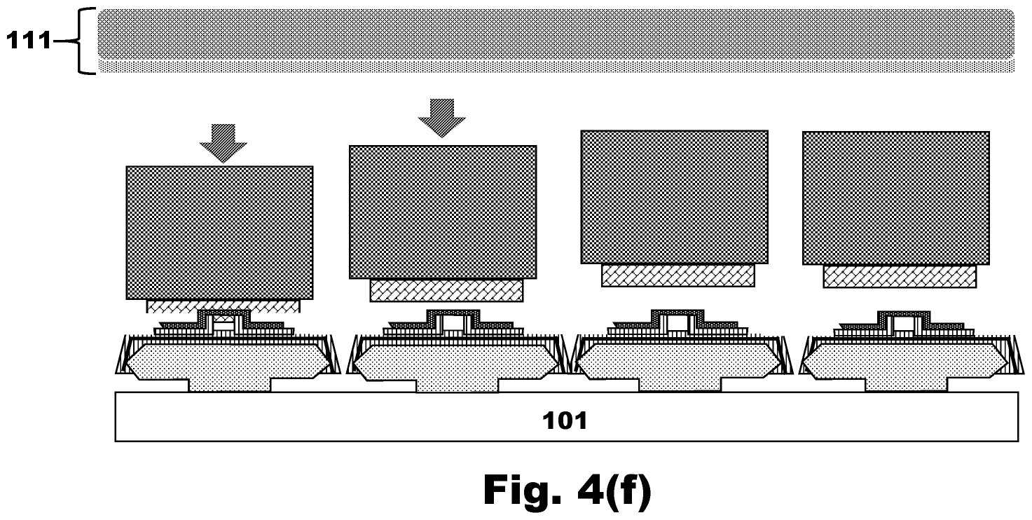

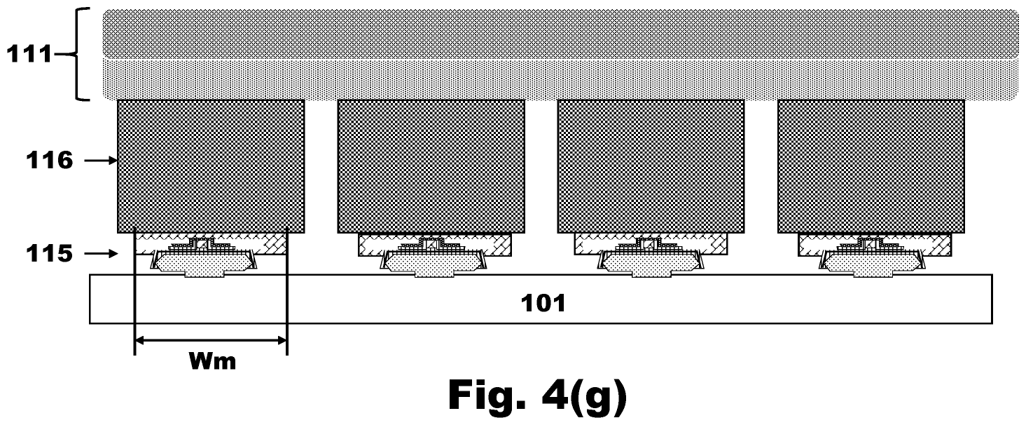

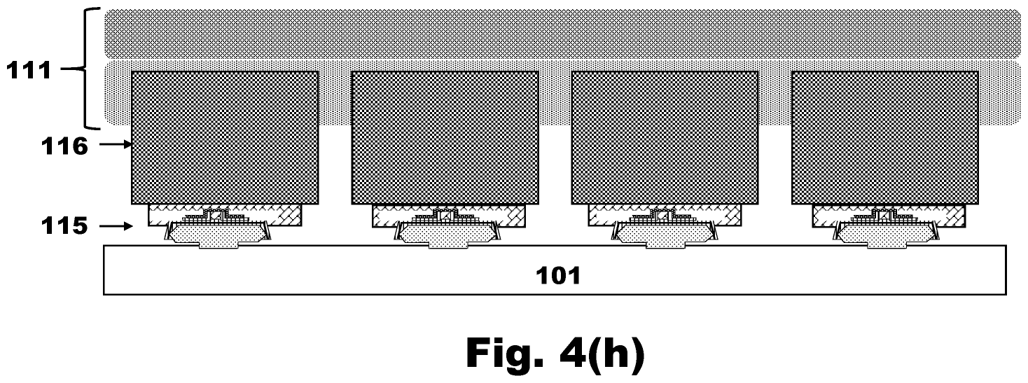

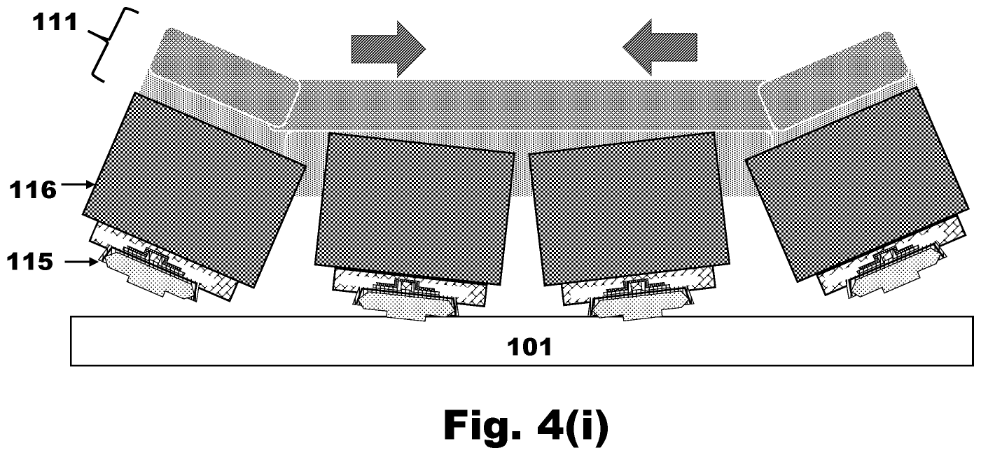

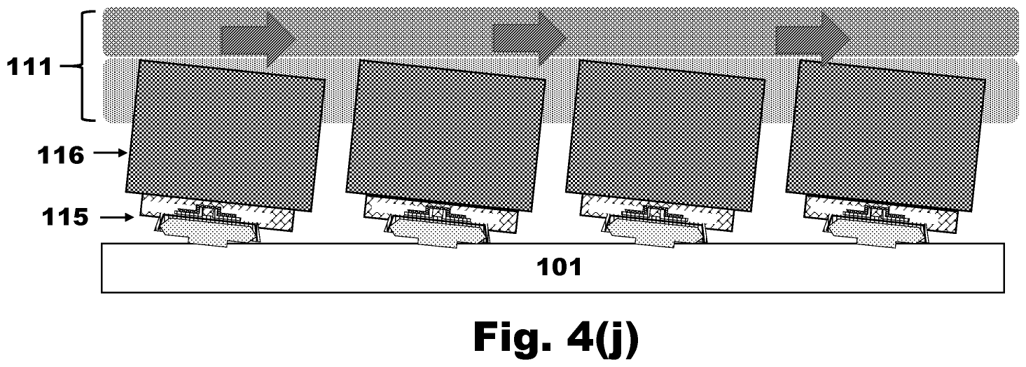

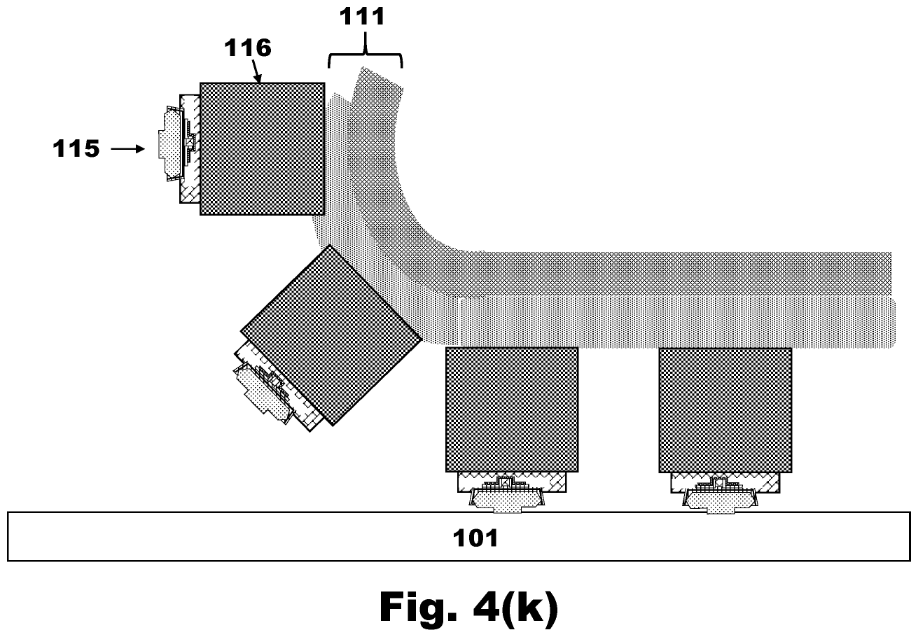

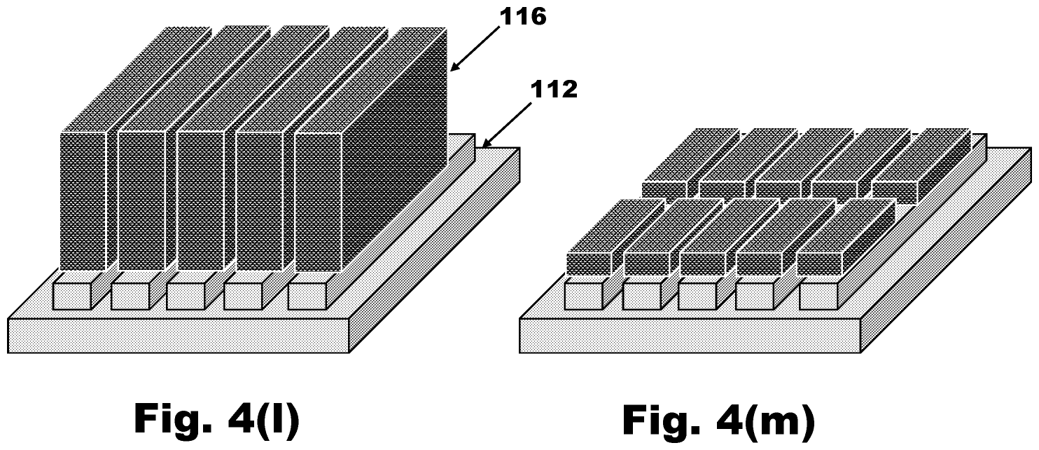

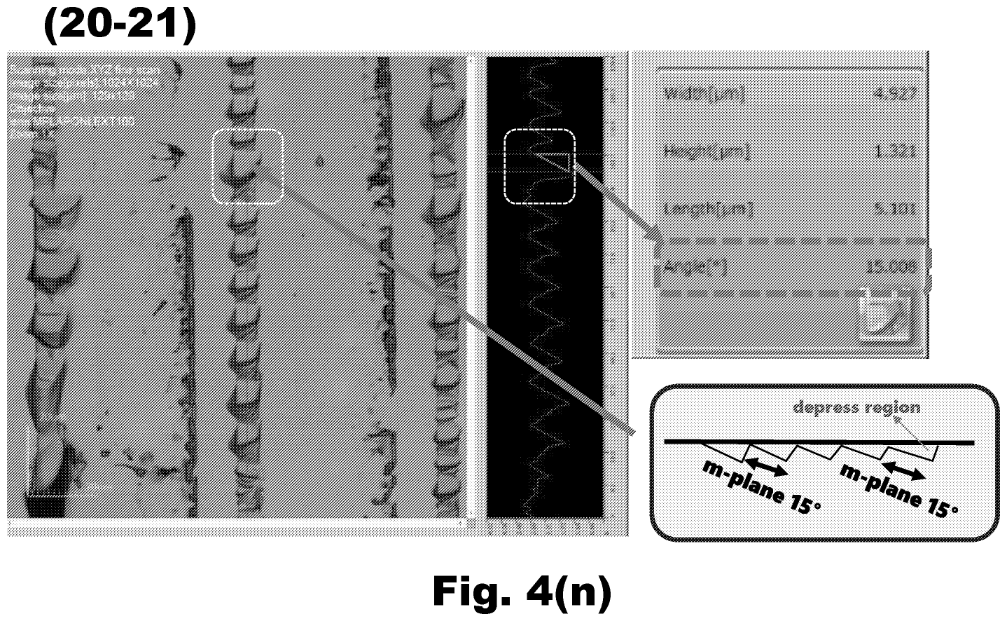

FIGS. 4(a)-4(e) illustrate a second case for the structure of the devices and the process flow for fabricating the devices, according to the present invention.

Process 1: Depositing the growth restrict mask 102 on the substrate 101 with the remaining surface exposed by striped opening areas 103 in the growth restrict mask 102, as shown in FIG. 4(b).

Process 2: Growing the In-nitride ELO layers 105A on the substrate 101 using the growth restrict mask 102, such that the growth extends in a direction parallel to the striped opening areas 103 of the growth restrict mask 102, and the Ill-nitride ELO layers 105A do not coalesce, as shown in FIG. 4(c).

Process 3: Removing the substrate 101 with the III-nitride ELO layers 105A from the MOCVD reactor, wherein at least a part of the growth restrict mask 102 is removed by dry or wet etching with an etchant such as HF or BHF, as shown in FIG. 4(d). Eliminating the growth restrict mask 102 before the growth of the Ill-nitride device layers 106 prevents the surface roughness from deteriorating. Removing the growth restrict mask 102 decreases the supply of excess gases to a side facet of the III-nitride ELO layers 105A. It also can help to obtain a smooth surface on the III-nitride device layers 106, which form island-like III-nitride semiconductor layers. By doing this, it can also avoid the compensation of the p-type layer by decomposed n-type dopants from the mask 102, such as Silicon (Si) and Oxygen (O) atoms.

Process 4: Growing the I-nitride device layers 106, as shown in FIG. 4(d). Adjacent bars 115 do not coalesce after the growth of the III-nitride device layers 106.

Process 5: Fabricating the device at the flat surface region by conventional methods, wherein the ridge structure, p-electrode, pad-electrode, etc., are disposed on the III-nitride device layers 106 at pre-determined positions, as shown in FIG. 4(e).

By doing this, bars 115 of devices can be obtained. Also, the breaking point 113, which is a removing position 113, can be obtained utilizing the growth restrict mask 102, as shown in FIG. 1(h).

Case 3:

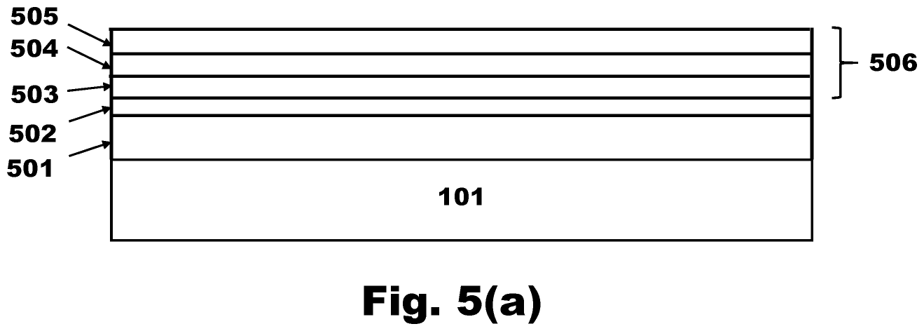

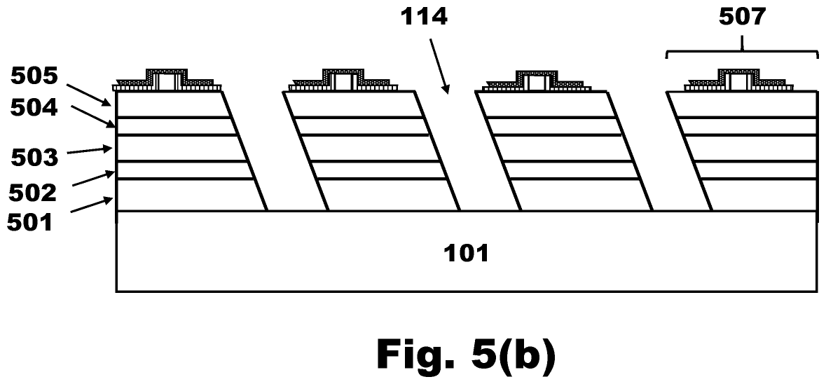

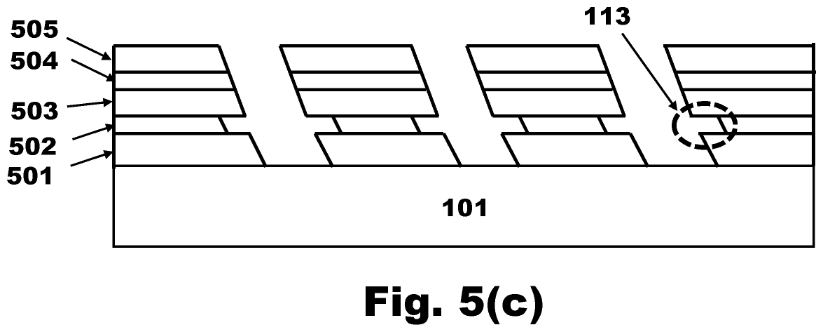

This case is illustrated in FIGS. 5(a)-5(c), which describe a method for manufacturing bars without using the ELO technique, comprising the steps of:

Process 1: Providing a III-nitride substrate 101; growing one or more InAlGaN-based layers 501-505 on the III-nitride substrate 101, as shown in FIG. 5(a). At that time, the InAlGaN-based layers includes sacrificial layers 502 in order to decide a removing position. In this case, the location of the sacrificial layers 502 become a removing position.

Process 2: Fabricating the device structure 507 on the III-nitride device layers 506, which includes p-type layers, active layers and n-type layers and so on, as shown in FIG. 5(b).

Process 3: Etching a part of the InAlGaN-based layers 501-505 by a conventional dry etch method, as shown by etching region 114 in FIG. 5(b). The dry etching is implemented until the sacrificial layers 502 are exposed for the sake of the removing of a part of the sacrificial layers 502 by wet etching, as shown in in FIG. 5(b).

Process 4: Etching a part of the sacrificial layers 502 to make a depressed region at the edge of the sacrificial layers 502 by wet etching method. Conventional methods can be used, including etchants such as KOH, NaOH, aqua regia, etc.

A photo-electro-chemical (PEC) etching method can be used as well. If a PEC etching method is used, the sacrificial layers 502 should include Indium to facilitate the etching, such as InAlGaN sacrificial layers 502, which have a band-gap larger than a wavelength of an ultraviolet (UV) light source, which can be used when using PEC etching. For example, a 405 nm UV light can be used and the band-gap of the sacrificial layers 502 is larger than 3.06 eV. In this case, the sacrificial layers 502 can absorb the UV light to generate the electrons and holes during PEC etching.

By doing this, bars 115 can be obtained, and the removing position 113 is made to utilize the depressed region at the edge of the sacrificial layers 502.

Step 2: Determine a Removing Position for Each of the Bars

In the present, there are several methods to determine the removing position 113.

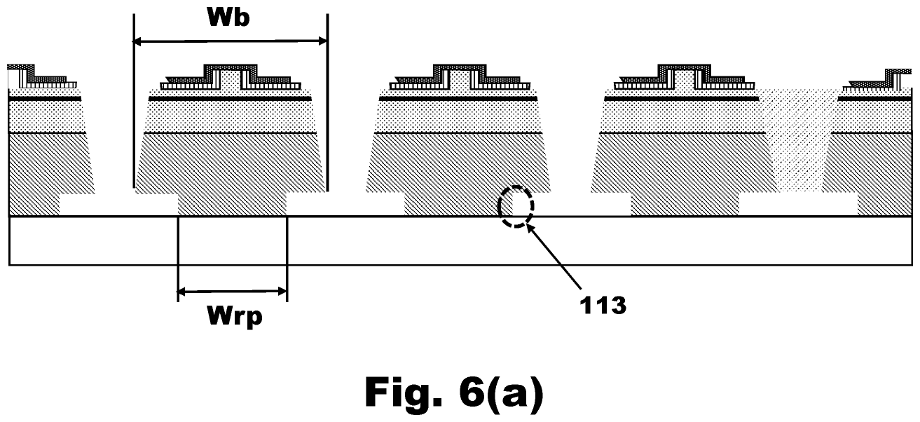

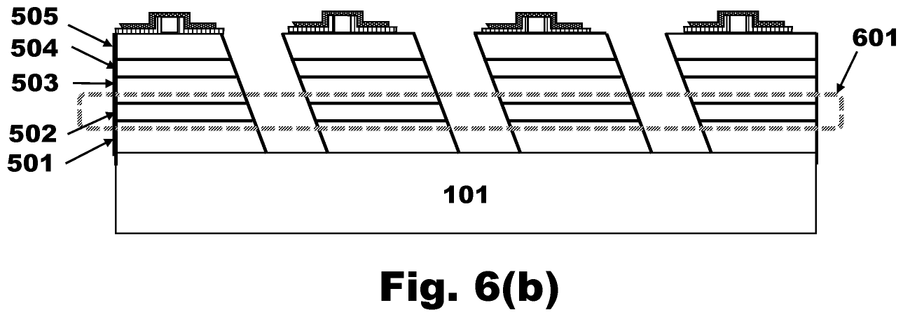

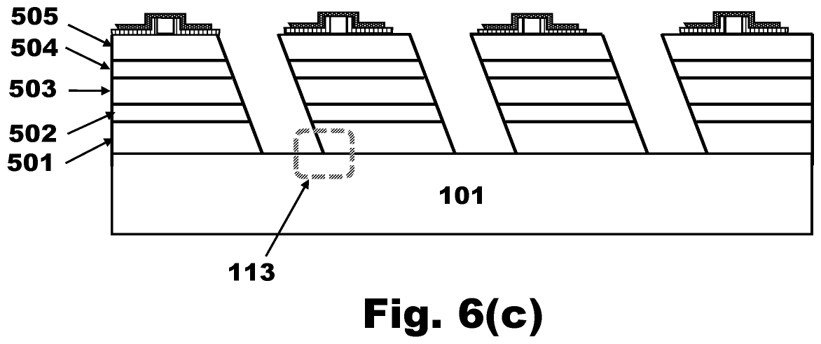

One method is to form a region that is narrower than the width Wb of the bar 115, as shown in FIG. 6(a), which is the width Wrp of the removing position 113. In other words, the width Wrp of the removing position 113 is narrower than the width Wb of the bar 115. Etching the growth restrict mask 102 and the sacrificial layers 502 plays a role on forming the removing position 113. This method is easy and precise to determine the removing position 113.

Moreover, FIG. 7 shows the situation at around of the edge of the growth restrict mask 102. It can be seen that there is a strong contrast at around the edge portion of the growth restrict mask 102, which indicates the existence of the stress. It can also indicate many defects. These phenomena were caused by the difference of the thermal expansion co-efficient between the epilayers and the growth restrict mask 102. It is thought that these stress and defects help cracks to happen at this region. As these reasons, this method is suitable for removing the bars from substrate by the present invention.

Another method, as shown in FIG. 6(b), is to form a region 601 which is the most fragile layer of the bar 115, for example, where there is a highly Si-doped layer, an InGaN layer, etc. A highly Si-doped layer is fragile because it has internal stress and many defects. An InGaN layer is more fragile than other III-nitride layers. Thus, these fragile layers can provide the removing position 113.

Still another method is to form a region where stress is applied most strongly from the supporting plates 116, as shown in FIG. 6(c). This region becomes the removing position 113. As shown in FIG. 6(c), when the bar 115 is formed, it can use an angle etching method. By doing this, it can determine the removing position 113.

The present invention can utilize these methods of determining the removing position 113, as set forth above. The present invention can also combine these methods.

Step 3: Bonding One or More Supporting Plates to the Bars

Step 3 can be divided into at least two parts. A first part is to fabricate a device structure on the bars 115, and a second part is to bond the supporting plates 116 with the bars 115.

<Fabricating a Device Structure Section>

Fabricating the device on the surface of the bar 115, which is comprised of U-nitride device layers 106, can be done by conventional methods, with a ridge structure, p-electrode, pad-electrode, etc. In the present invention, many kinds of devices can be fabricated on bars 115 by conventional methods using conventional structures.

<Bonding Section>

Various bonding techniques can be used with the present invention, which are applicable for the fabrication of devices by removing bars 115, as described below. This includes diffusion bonding, eutectic bonding (Au—Sn solder, Si—Au), and transient liquid phase bonding (Pd—In bonding). These bonding methods can be adapted for any devices, such as laser diodes, LEDs, electronics devices, sensors and so on.

Bonding supporting plates 116 to the bars 115 aims to transfer the stress applied by the supporting plates 116 to the removing position 113 effectively to facilitate removal of the bar 115. Enhancing the height of the bar 115 is of critical importance to removing the bar 115 at the removing position 113. Moreover, there are no problems if the bonding strength between the bar 115 and the supporting plates 116 is stronger than the strength of removing the bar 115 at the removing position 113. Within this range, any bonding materials can be used, such as solders, adhesives, metals and so on.

Following are various cases for bonding methods that can be adapted to the present invention.

Case 1: Solder

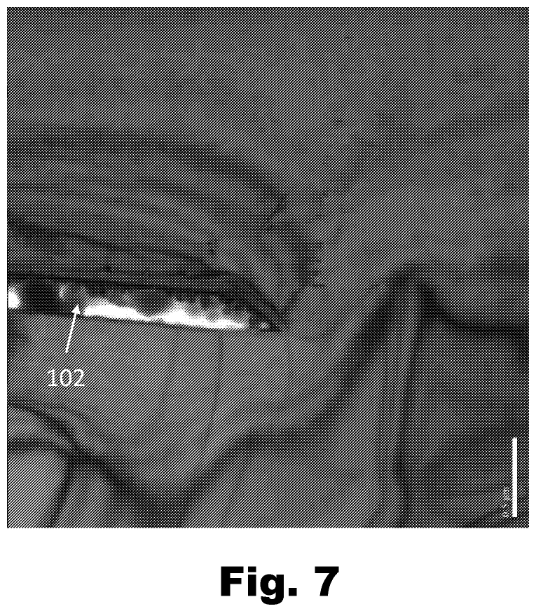

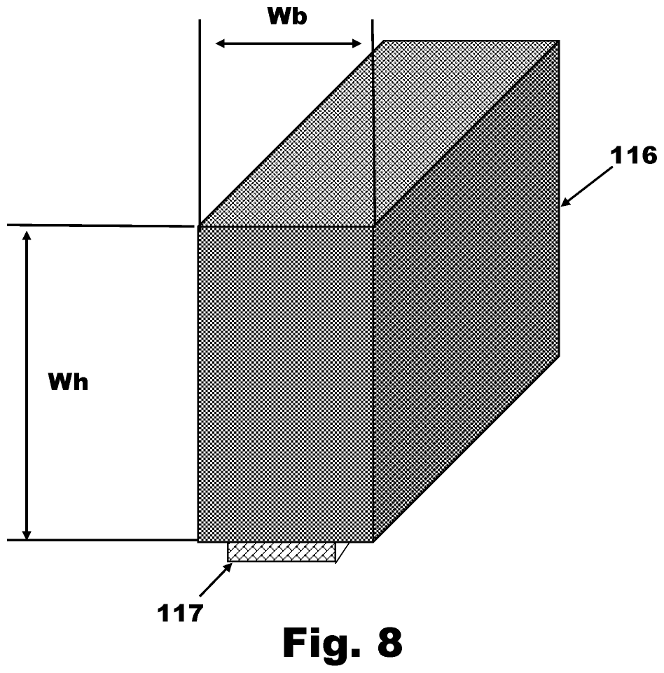

In this case, conventional solder, such as Au—Sn, Sn—Ag—Cu, etc., can be used, as shown in FIGS. 8, 9(a) and 9(b), and 10(a) and 10(b), which explain how to bond bars 115 and supporting plates 116. For example, if an Si substrate is selected as a supporting plate 116, solder including Sn is suitable for the present invention in terms of bonding strength, bonding temperature and low resistivity.

In the example shown in FIG. 8, the Si supporting plate 116 has Au—Sn solder 117 on its surface.

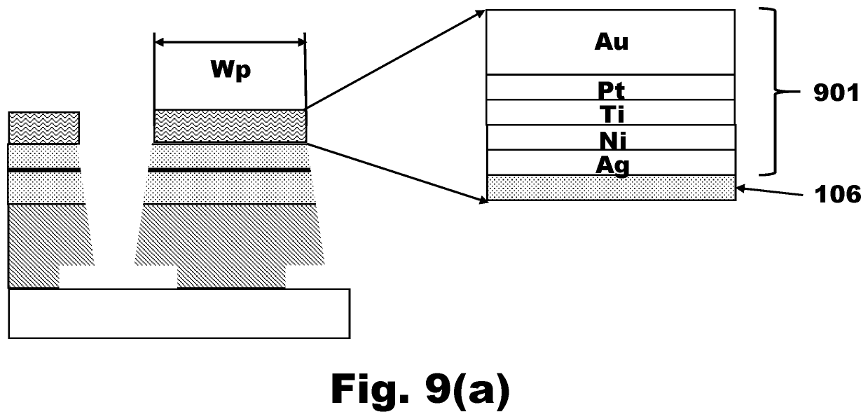

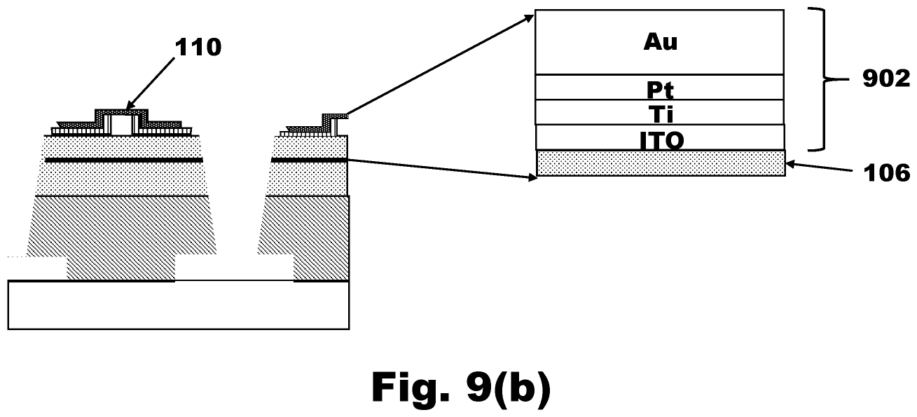

The examples shown in FIGS. 9(a) and 9(b) illustrate bonding to a conventional LED device structure and a conventional LD device structure, using a p-electrode configuration.

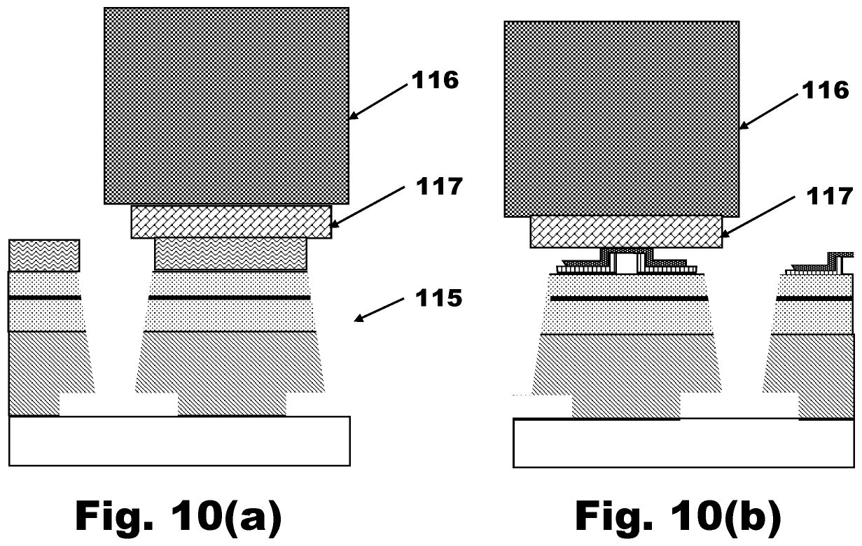

In the LED case, the electrode of LED 901 comprises an Ag layer that directly contacts a p-type layer of the LED to reflect emitted light. The Ni, Ti and Pt layers are used to adhere and prevent interdiffusion. The supporting plate 116 and the LED bar 115 are bonded at 250-300° C., as shown in FIG. 10(a).

The use of Pd—In can provide some advantages to the devices. If removed bars 115 comprise LED devices, those devices require high reflectivity at a bonding portion. For example, low temperature transient liquid-phase Pd—In bonding is implemented at around 200° C. The Pd layer is disposed on the surface of the top of bars 115 and the Pd—In layer is disposed on the supporting plates 116. These structures are then bonded with each other at low temperature. A Pd—In₃ intermetallic compound is formed by interdiffusion during heating, which improves the bonding strength due to a high melting temperature over 600° C.

As another candidate, Au and Si eutectic bonding may be used between GaN and Si substrates at 400° C., with a process time of 30 min under 5 MPa.

Ag—Au and Ag—Al diffusion bonding is performed at 150° C. In the LED case, Ni (1 nm: thin layer) may be used to enhance reflectivity in Ni/Ag/Au layers as an LED's p-electrode, which is bonded to Au with an Si sub-mount.

Case 2: Adhesive

In this case, adhesives can be used to bond bars 115 and supporting plates 116. The adhesives can be epoxies or polymetric adhesives. Candidate materials include the following: polyimide, 2-part epoxies, benzocyclobutene (BCB: C₈H₆) and UV-curable photopolymer such as SU-8. For example, benzocyclobutene (BCB: C₈H₆) is heated at 200° C. for 60 min when bonding.

Applicators of different adhesives are designed according to the adhesive being used and the size of the area to which the adhesive will be applied.

Case 3; Au—Au Bonding by a Surface-Activation Method

In this case, the bar 115 and the supporting plate 116 can be bonded without solder. Thus, the feature of this bonding is a high thermal conductivity. This is similar to case 1, except for the bonding material 117. In this case, the bonding material 117 is gold (Au) and the supporting plate 116 is preferably Silicon (Si). The bar 115 and the supporting plate 116 are bonded without solder using gold at 300-400° C.

It is preferable to perform an activation of the bonding surfaces before Au—Au bonding is performed. The activation of the bonding surfaces is achieved using a plasma process of Ar and/or O₂. The bars 115 are then bonded to the supporting plates 116 at 150-300° C. under pressure.

Case 4: Reflow Bonding

In this case, conventional reflow bonding is used for the sake of self-alignment.

If conductive bonding materials are used, they should cover at least the side facets of the bar 115 with an insulating layers, such as SiO₂, Al₂O₃, Zr₂O, etc., to prevent the leakage of current. Preferably, the insulating layer covers the side facet totally.

<Supporting Plates Material>

The following refer the types of materials used for the supporting plates 116.

Case 1: Single Crystal Supporting Plate

In this case, the supporting plate 116 is a single crystal, such as SiC, Si, AlN, GaN, etc. When Si is used as the supporting plate 116, it has the following advantages:

1. high thermal conductivity,

2. low resistivity,

3. easier microfabrication,

4. utilizing an atomically flat surface of Si, Au—Au bonding can be used without solder, and

5. low cost.

Thus, using an Si supporting plate 116 is suitable for the present invention. Other materials such as SIC, AlN and GaN etc. can be used as a supporting plate 116.

Case 2: Metal Supporting Plate

In this case, the supporting plate 116 is metal, such as Cu, CuW, Al, stainless steel, etc. This has the benefit of high thermal conductivity.

Case 3: Ceramic Supporting Plate

When insulation is necessary for a supporting plate 116, good candidates are ceramic materials, such as Al₂O₃, as well as AlN, SiC, etc. A ceramic supporting plate 116 can also obtain high thermal conductivity.

Generally, many semiconductor lasers adopted this type of sub-mount on a stem, such as a TO-can package, for the reasons of low cost, insulation and a high thermal conductivity.

In the present invention, it does not matter whether the supporting plate 116 is conductive or not. A supporting plate 116 with via holes filled with Ag, etc., can also be used to improve the thermal conductivity and reduce electrical resistivity.

A supporting plate 116 made of ceramics is hard and durable, which makes it is easy to handle without breaking, especially when the supporting plates 116 have a large ratio of longitude length and lateral length. Hardness and robustness are very important elements to supporting plates 116.

<Supporting Plates Shapes>

The following refers the shapes of the supporting plates 116.

Case 1: Separated Supporting Plates

This case uses separated supporting plates 116, wherein the supporting plate 116 is a fin. In a separated fin-type supporting plate 116, the fins are separated individually and placed on bars 115. The fins may be arranged one by one on bars 115, or a plurality of the fins may be arranged on the bars 115 at the same time. Then, pressure is applied to the fins by the plates 116, and the bars 115 and plates 116 are heated for bonding. By doing this, the bonding process completes.

This type of supporting plate 116 has an advantage in that, even when the bars 115 have different heights, these supporting plates 116 can easily bond to the bars 115 due to their having flexibility.

It may happen that the bars 115 have different heights when the bars 115 are grown using the ELO technique. In this case, the separated fin-type supporting plates 116 is preferable.

Case 2: Holding Supporting Plates

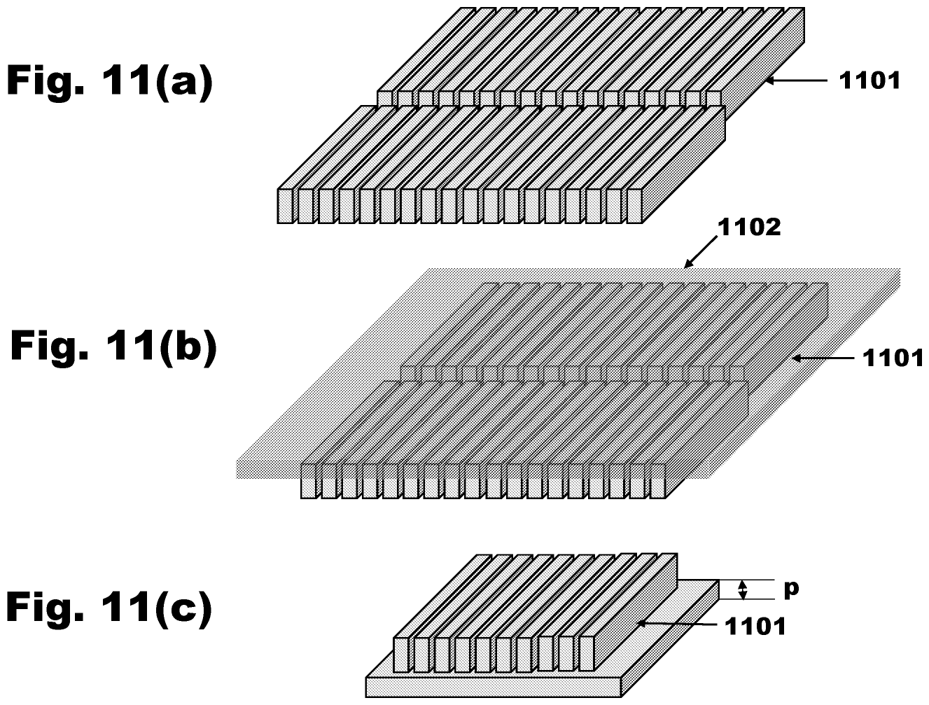

This case uses holding-type supporting plates 116, wherein the supporting plate 116 is a fin. In holding-type supporting plates 116, the fins 1101 are arranged on a film 1102, as shown in FIGS. 11(a), 11(b) and 11(c). There are two kinds of holding-type supporting plates 116, as described below.

Case 2-1: Different Materials

This kind of holding-type supporting plates 116 is comprised of different materials for the fin 1101 and the film 1102. Fins 1101 have been adhered to the film 1102, after which the fins 1101 can be removed.

The film 1102 can be a heat-resistant film, such as a fluoro-resin film, polyimide film, etc. The film 1102 also can be heat-resistant, which has a thermal expansion co-efficient close to the substrate 101 with bars 115, for the sake of a precise bonding position.

If the film 1102 is a flexible film, it is effective even if the heights of the bars 115 are different.

Case 2-2: Same Material

This kind of holding-type supporting plates 116 is comprised of the same materials for the fin 1101 and the film 1102, as shown in FIG. 11(c).

In this case, the advantages are that it is easy to handle the fins 1101 and to precisely arrange the fins 1101 with respect to the corresponding bars 115.

For example, making a film 1102 with fins 1101 from a Silicon substrate can be relatively easily achieved using a dry etching and a wet etching method, such as the structure shown in FIG. 11(c). In this case, since the distance between adjacent bars 115 and the direction is fixed, there is less possibility to mis-align against the bars 115. Also, in terms of yield, this configuration is preferable.

However, since the fins 1101 and the film 1102 have less flexibility, the thickness p of the film 1102, as shown in FIG. 11(c), is set to be thin enough to be able to bend the film 1102. By doing this, it can correspond to the difference of the height of the bars 115, even using this type of supporting plate 116. Especially, when using Silicon, it is preferable that the thickness p is less than 200 μm to make it easy to bend.

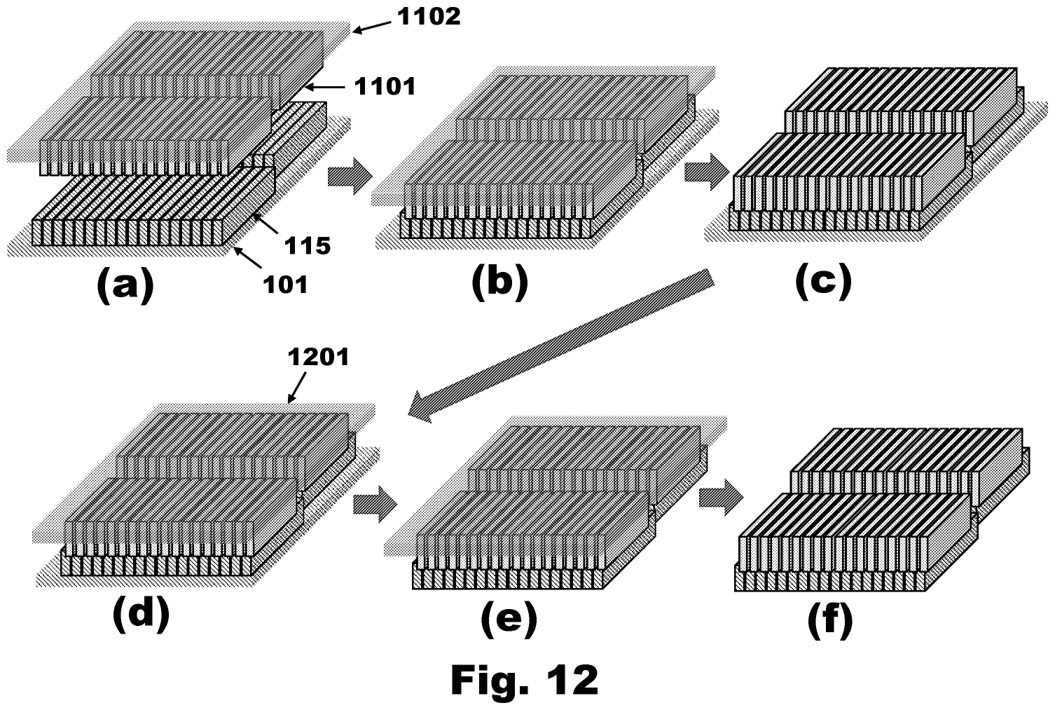

The fins 1101 and the film 1102 are arranged on the substrate 101 with bars 115, as shown in FIGS. 12(a)-12(c). Then, pressure is applied to the film 1102 and fins 1101, and the structure is heated for bonding. By doing this, the bonding process completes.

The film 1102 and fins 1101 are removed, as shown in FIGS. 12(d)-12(f), using another polymer film 1201, which has larger thermal expansion co-efficient than the substrate 101 with bars 115, that is attached to the fins 1102, as shown in FIGS. 12(d)-12(f).

Step 4: Apply a Stress to the Supporting Plates to Remove the Bars at the Removing Positions

Step 4 applies a stress to the supporting plates 116, which may occur in a variety of ways, to remove the bars at the removing positions.

Case 1: Separated Supporting Plates

This case includes separated supporting plates 116, wherein the supporting plates 116 are fins. As shown in FIGS. 4(g)-4(k), one or a plurality of supporting plates 116 are disposed on the bar 115, in the direction of the parallel of the bar 115. Pressure and heat are applied to the supporting plates 116 and substrate 101. Then, after cooling, the following procedure is used for removal:

Process 1: Attaching a polymer film 111 to the bar 115 of the device, as shown in FIG. 4(g).

Process 2: Applying pressure to the polymer film 111 and the substrate 101, as shown in FIG. 4(h).

Process 3: Reducing the temperature of the polymer film 111 and the substrate 101 while the pressure is applied.

Process 4: Utilizing the difference in the thermal coefficient between the polymer film 111 and the substrate 101 for removing the bar 115 of the device.

The stress can be created from the difference in the thermal expansion co-efficiency, and can be applied to the supporting plates 116, which can remove the bars 115 from the substrate 101 without contacting the polymer film 111 to the bars 115. By doing this, it can effectively apply the stress at the removing position.

Various methods may be used to reduce the temperature. For example, the substrate 101 and the polymer film 111 can be put into liquid N₂ (for example, at 77° K) at the same time while applying pressure. The temperature of the substrate 101 and the polymer film 111 can also be controlled with a piezoelectric transducer. Moreover, the plate 116 that applies the pressure to the polymer film 111 can be cooled to a low temperature before and/or during contact with the polymer film 111. By doing this, the polymer film 111 is cooled and can apply pressure to the bar 115 due to a large thermal expansion coefficient.

When reducing the temperature, the substrate 101 and the polymer film 111 may be wetted by atmospheric moisture. In this case, the temperature reduction can be conducted in a dry air atmosphere or a dry N₂ atmosphere, which avoids the substrate 101 and the polymer film 111 getting wet.

Thereafter, the temperature increases, for example, to room temperature, and the pressure is no longer applied to the film 111. At that time, the bar 115 has been already removed from the substrate 101, and the polymer film 111 is then separated from the substrate 101.

Using the separated supporting plates 116 can improve flexibility and obtain a working area that provides a space to be able to move the supporting plates 116. These are critical advantages for the removal.

Another way is shown in FIG. 4(j), which does not utilize the different thermal expansion co-efficiency. This method simply applies the stress mechanically to the supporting plates 116. Moreover, by enhancing the adhesiveness of the polymer film 111, peeling off the polymer film 111 only results in being able to remove the bars 115 from the substrate 101 due to the existing of the supporting plates 116 effectively applying the stress to the removing position, as shown in FIG. 4(k).

Case 2: Holding-Type Supporting Plate

This case includes a holding-type supporting plate 116, wherein the supporting plate 116 is a fin 1102.

Case 2-1: Different Materials

In the case of different materials, the film 1101 and fins 1102 are arranged on the substrate 101 with bars 115, as shown in FIGS. 12(a)-12(b). Then, pressure is applied to the fins 1101, and the film 1102 and fins 1101 are heated for bonding. By doing this, the bonding process completes.

The film 1102 is removed, as shown in FIG. 12(c). Another polymer film 1201, which has a larger thermal expansion co-efficient than the substrate 101 with bars 115, is attached to the fins 1101, as shown in FIG. 12(d). The temperature of the polymer film 1201 and substrate 101 is reduced, while pressure is applied, wherein the polymer film 1201 shrinks as the temperature decreases. As a result, the polymer film 1201 can apply pressure in a horizontal direction at side facet of the fin 1101. This pressure applied from the side facet allows the fin 1101 to be effectively removed from the substrate 101, as shown in FIG. 12(e). During low temperature, the polymer film 1201 maintains the pressure applied from the top of the film 1201 to the fins 1101. Finally, the polymer film 1201 is removed from the fins 1101 with bar 115, as shown in FIG. 12(f).

Case 2-2: Same Materials

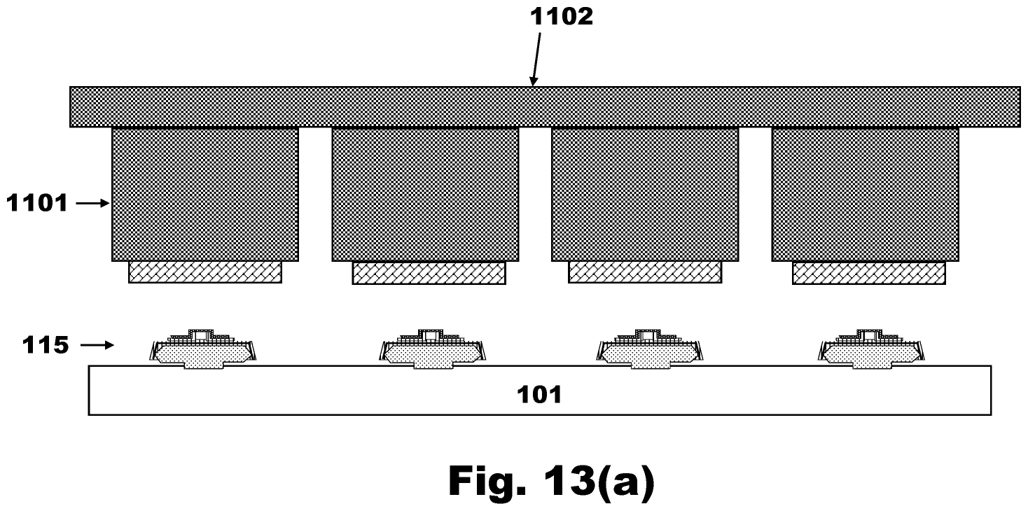

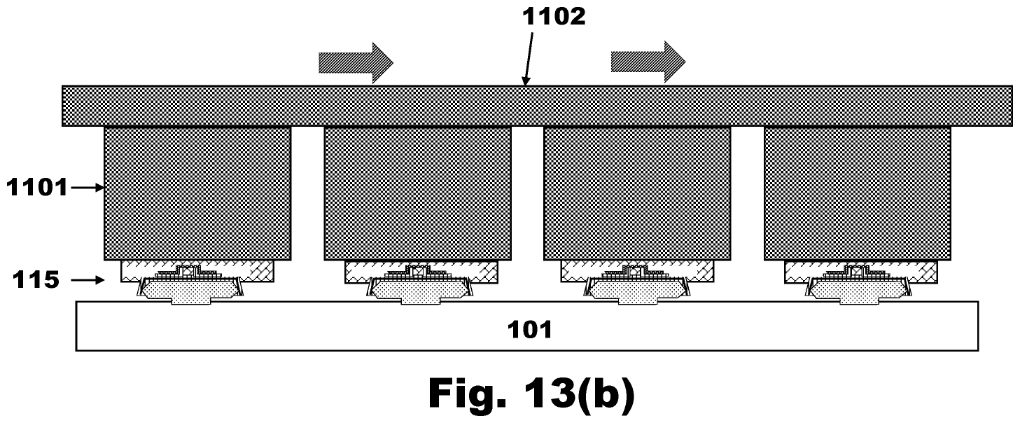

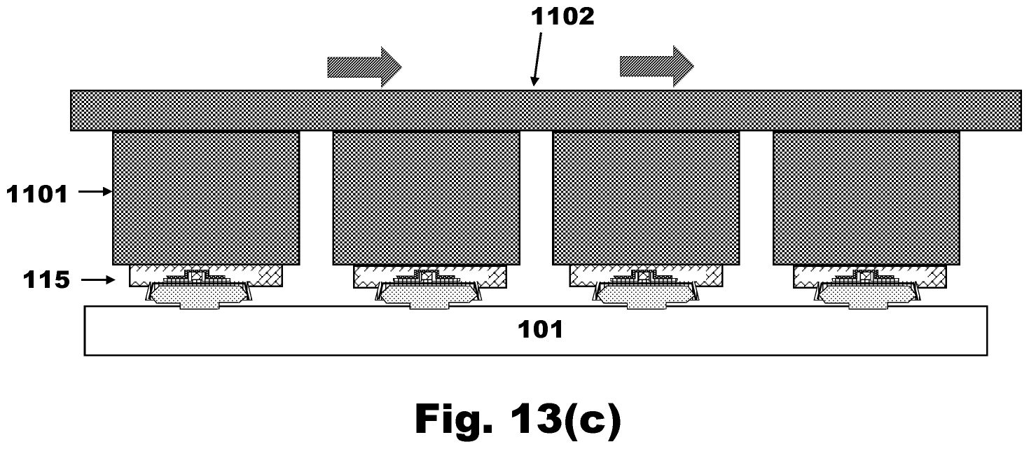

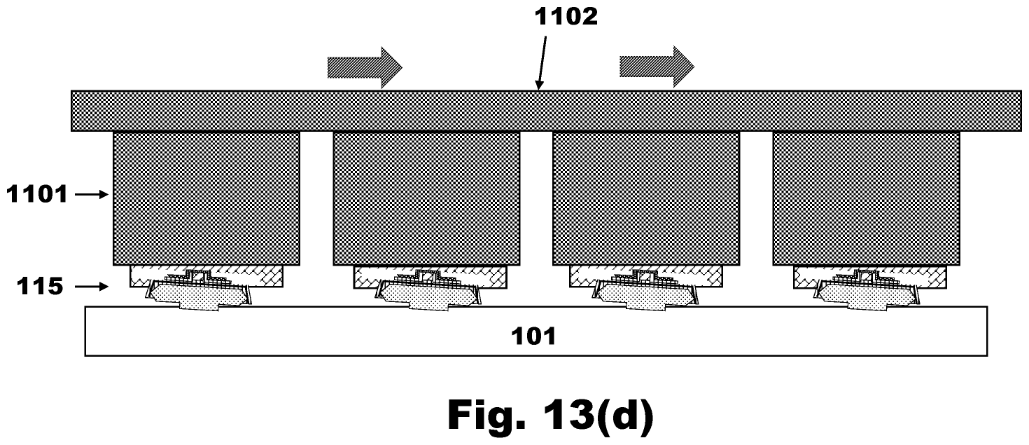

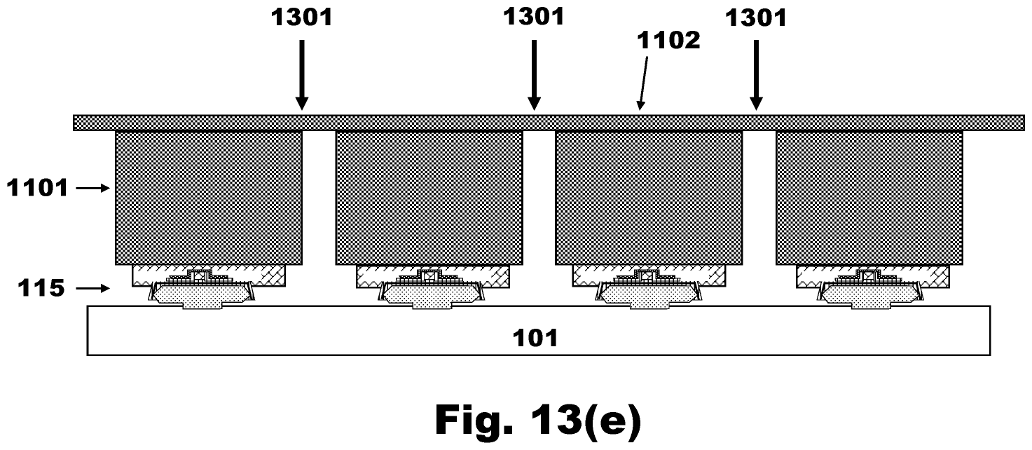

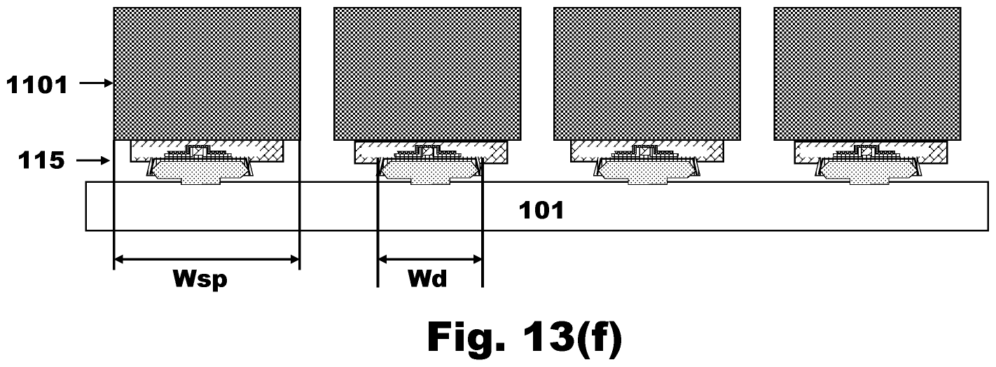

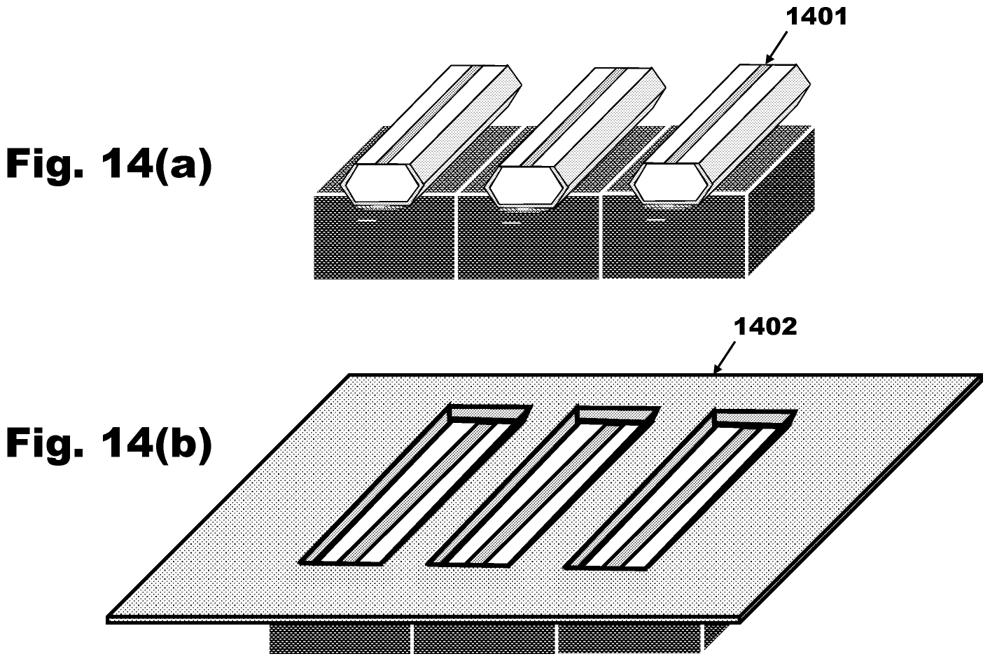

In the case of the same materials, the fins 1101 and film 1102 are same materials, such as Silicon, etc., as shown in FIG. 11(c). The fins 1101 and film 1102 can be fabricated from a Silicon substrate using a conventional method, such as photolithography, dry and wet etch processes, etc. Then, the fins 1101 and film 1102 are bonded to the bars 115 and substrate 101 by a bonding method, as set forth as shown in FIGS. 13(a) and 13(b).

When a holding plate is a supporting plate, it applies stress to the holding plate, as shown in FIG. 13(c). In this case, the stress can be applied efficiently to the removing position, as shown in FIG. 13(d), so that it can remove the bars 115 from the substrate 101. Bonding solder, metal and adhesive material might provide a buffer to protect the bars 115.

This also describes a preferable method that can be used when removing. As shown in FIGS. 13(e) and 13(f), part of the holding plate is removed by wet or dry etching 1301 process, which results in dividing the supporting plate. The rest of the process from here is the same as described in Case 1: Separated supporting plate. This method has a critical advantage, in that bonding the holding plate having fins to bars 115 on the substrate 101 can make precise alignment and bonding multiple bars simultaneously possible. This can increase yield and efficacy.

Moreover, other methods can be used in order to remove a holding plate.

<Utilizing the Cleavability of the GaN Crystal>

It is preferable that, when removing the bar 115, it utilizes the cleavability of a GaN crystal, especially along an m-plane and c-plane, which are known as cleavage planes.

Utilizing the cleavage plane for the removal of bars 115 can remove the bars 115 without excess stress, which is much preferable.

Moreover, it has been discovered that bars 115 may be removed by utilizing the cleavability of GaN without using a cleavage plane. As shown in FIG. 4(l), this substrate 101 is a (20-21) plane, which is not a cleavage plane, and tilts 15 degrees from the m-plane. However, the substrate 101 surface after removal includes an m-plane surface. This was able to be confirmed by measuring the angle of the surface.

The present invention can utilize this phenomena. In other words, utilizing the cleavability of the cleavage plane, such as c-plane and m-plane, in other plane that is not a cleavage plane, such as (30-31), (30-3-1), (20-21), (20-2-1), (10-11), (10-1-1), etc., provides a big advantage in removing the bars 115. Thus, it is much preferred to let a part of the substrate 101 surface after the removal appear as a cleavage plane.

This is a very useful and a powerful method that can be utilized for the removal of other planes, such as (11-22) (1-10-2), (1-102), and so on.

Step 5: Implement Additional Device Processes after the Removal of the Bars

Step 5 implements device processes after the removal of the bars 115. However, some or all of these device processes can be implemented before the removal of the bars 115.

For example, the processes after the removal may include an n-electrode deposition to the back side of the bars 115, forming the facet by cleaving, coating of the facet, and so on.

<Disposing the n-Electrode at the Separate Area>

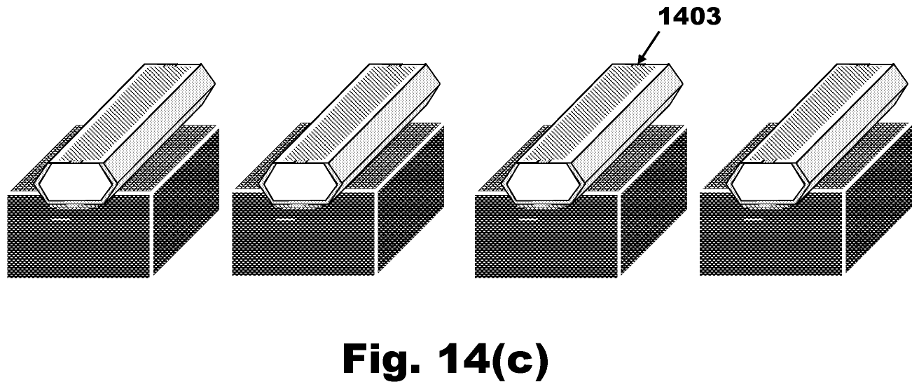

After removing the bar 115 from the substrate 101, as shown in FIG. 14(a), the bars 115 are bonded the supporting plates 116. FIG. 14(a) shows the back side of the bar 115, which has a separate area 1401. The separate area 1401 contacts the substrate 101, or the underneath layer directly, but is not on the growth restrict mask 102 area.

Then, as shown in FIG. 14(b), the method of disposing the n-electrode can use a metal mask 1402 method. The n-electrode can be disposed on the back side of the III-nitride device layers 106 using the metal mask 1402. The bar 115 height is over 10 μm, so it is preferable to use the metal mask 1402 method to dispose the n-electrode. Moreover, if the size of the bar 115 is small, a collet which transfers the bar 115 to a process that can contact the supporting plate without touching the bar 115. This can reduce the chance to damage the bar 115.

Typically, the n-electrode is comprised of the following materials: Ti, Hf, Cr, Al, Mo, W, Au. For example, the n-electrode may be comprised of Ti—Al—Pt—Au (with a thickness of 30-100-30-500 nm), but is not limited to those materials. The deposition of these materials may be performed by electron beam evaporation, sputter, thermal heat evaporation, etc.

In the case of forming the n-electrode 1403 of back side of the bar 115 after removing the bar 115 from the substrate 101, the n-electrode 1403 is preferably formed on the area including the separate area 1401, which is shown in FIG. 14(c). This area is kept good surface condition for the n-electrode 1403 to obtain low contact resistivity. The present invention keeps this area clean until removing the III-nitride device layers 106. Therefore, it is better to form the n-electrode 1403 at this area.

The n-electrode 1403 also can be disposed on the top surface, which is the same surface made for a p-electrode.

<Forming the Facet by Cleaving>

Using the supporting plates 116 when removing the bars 115 makes available many methods to form a facet. In other words, the supporting plate 116 can be used when making the facet it, as described in more detail below.

<Dividing Support Regions>

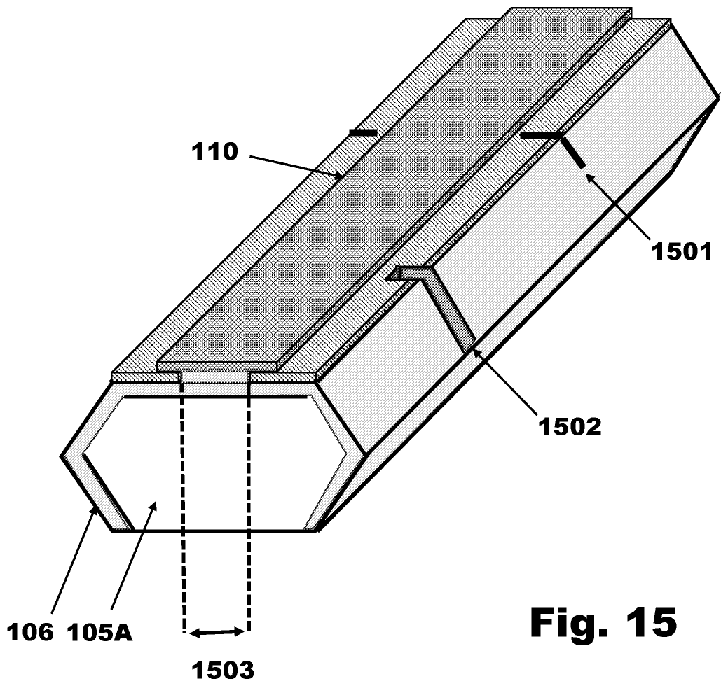

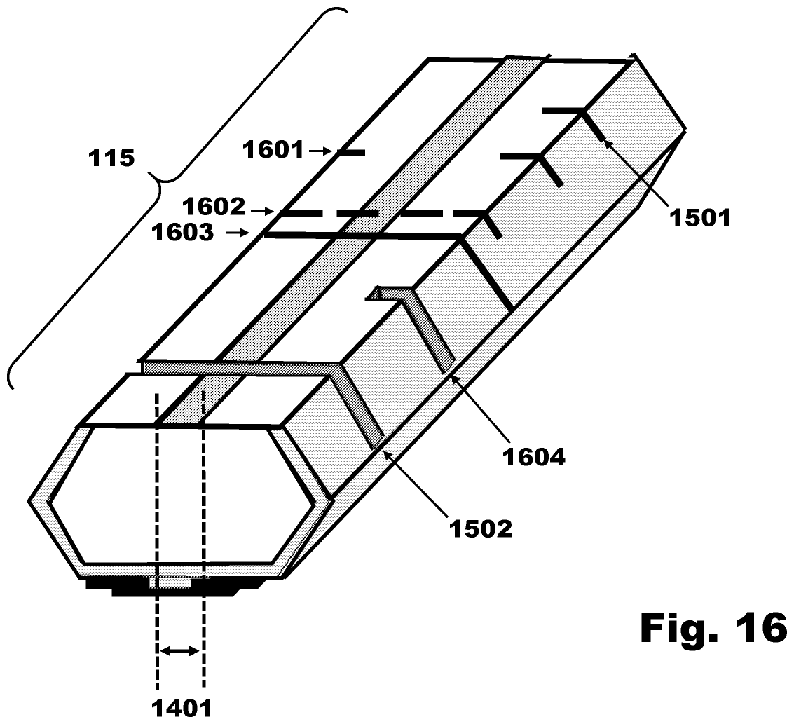

The aim of this step is to prepare to divide the bar 115 of the device before the bar 115 is removed from the substrate 101. As shown in FIG. 15, a dividing support region 1501 is formed at periodic lengths, wherein each period is determined according to device length. For example, in the case of an LD device, one period is set to be 300-1200 μm.

The dividing support region 1501 is a line scribed by a diamond tipped scriber or laser scriber; or a trench 1502 formed by dry-etching, such as Reactive Ion Etching (RIE) or Inductively Coupled Plasma (ICP), but is not limited to those methods. The dividing support region 1501 is formed on both sides of the bar 115 or on one side of the bar 115. The depth of the dividing support region 1501 is preferably 1 μm or more.

A number of methods can be used to divide the bar 115 into the devices, as described below. The dividing support region 1501 is weaker than any other part. The dividing support region 1501 avoids breaking the bar 115 at unintentional positions, so that it can precisely determine the device length, as shown in FIG. 15.

Also as shown in FIG. 15, the dividing support region 1501 is formed at the surface of the bars 115 to avoid the current injection region 1503, such as on the ridge structure, or the p-electrode 110.

Moreover, the dividing support regions 1501 can also be formed on the back side of the bar 115 where there is no current injection region 1503 like the top side of the bar 115. Thus, the dividing support regions 1501 can be formed in a variety of ways.

FIG. 16 shows the dividing support region 1501 and trench 1502 of FIG. 15, as well as other types of dividing support regions 1601, 1602, 1603, 1604, wherein 1501 is a scribed line on only one side of the bar 115, 1601 is a scribed line on both sides of the bar 115, 1602 is a scribed line which is dashed across the bar 115, 1603 is a scribed line which is contiguous across the bar 115, and 1604 is a dividing support region or partial trench formed by dry etching or laser scribing.

On the other hand, the bar 115 can be divided into one or more devices without the dividing support region 1501, trench 1502 or dividing support regions 1601, 1602, 1603, 1604. Nonetheless, it is much preferred to utilize a dividing support region 1501, trench 1502 or dividing support regions 1601, 1602, 1603, 1604. Furthermore, any combination of different types of dividing support regions 1501, 1601, 1602, 1603, 1604 or trenches 1502 may be used.

<Different Types of Supporting Plates>

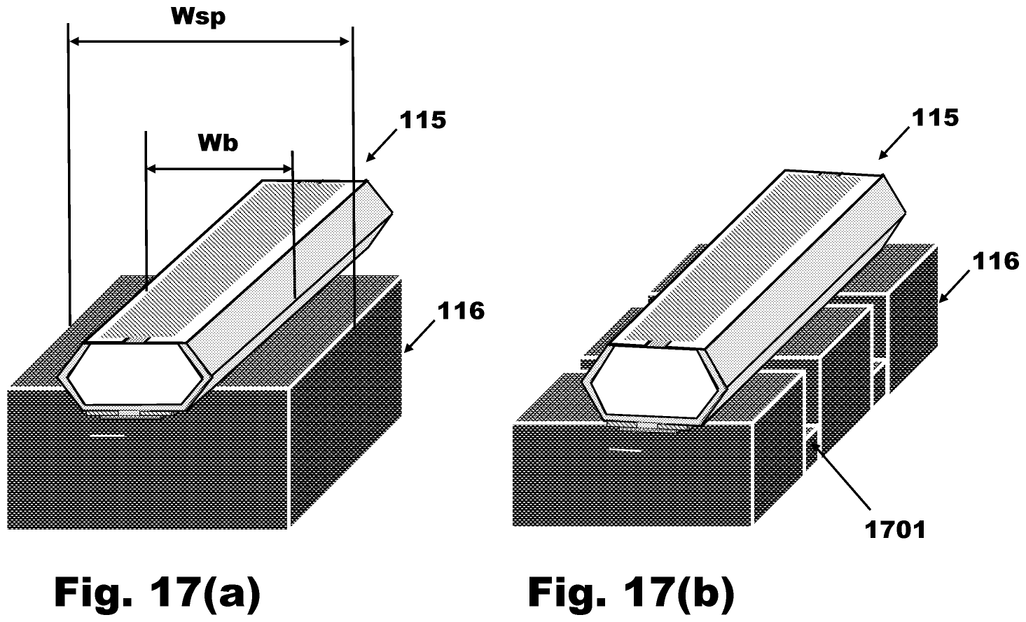

There are two types of supporting plates 116: without or with a depressed region 1701, as shown in FIGS. 17(a) and 17(b), respectively. These depressed regions 1701 help the bar 115 divide into two or more devices. Moreover, it also helps to make facets for the devices.

Supporting plates 116 can also help remove the bar 115 from a substrate 101 and divide the bar 115 into devices in a bonding situation. In this way, supporting plates 116 have many advantages.

There are a number of methods to divide the bar 115 into devices utilizing supporting plates 115, which are described below.

———Method 1———

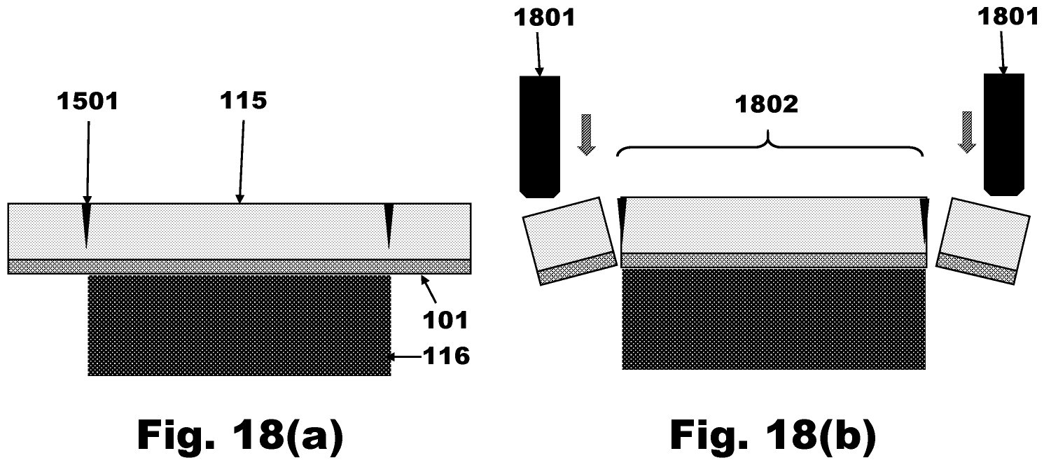

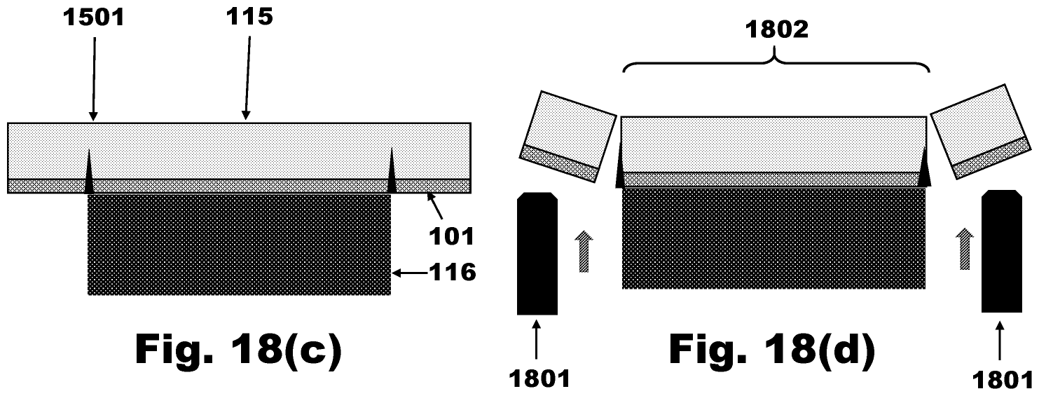

FIGS. 18(a) and 18(b) illustrate a first method of dividing the bar 115, and shows a cross-section of the bar 115 with a supporting plate 116. In this case, for the sake of making a cleavage facet, the supporting plate 116 has a length that is shorter than the bar 115. The use of the dividing support region 1501 is much better in obtaining a cleavage plane. In this method, the bar 115 has the dividing support region 1501 at the back side of the bar 115. After the removal of the bar 115 from a substrate 101, those regions 1501 are formed by a diamond tip scriber or laser scriber. The regions 1501 are located at the edge of the supporting plates 116. Then, collets 1801 apply a stress to the edge of the bar 115 in order to cleave the bar 115. The supporting plate 116 facilitates the cleaving by floating the edge of the bar 115.

Moreover, the bar 115 after the removal does not include substantially the substrate 101. The bar 115, which is made by MOCVD, MBE, etc., is of high crystal quality, while the substrate 101 often has some irregular portions, such as particles, dips, etc. When the substrate 101 and bar 115 are cleaved at the same time in a conventional method, the irregular portion of the substrate 101 may prevent the bar 115 from cleaving well in a straight manner.

Another way of making a facet is shown in FIGS. 18(c) and 18(d), which forms the dividing support region 1501 at the top side of the bar 115 before or after the bonding to the supporting plate 116. In this case, the collet 1801 applies the stress to the edge of the bar 115, which is floating from the supporting plate 116. Since the rest of the bar 115 is bonded to the supporting plate 116, it is easy to cleave the bar 115 at the dividing support region 1501.

The result of this method is a device unit 1802 comprised of the device with the supporting plate 116.

———Method 2———

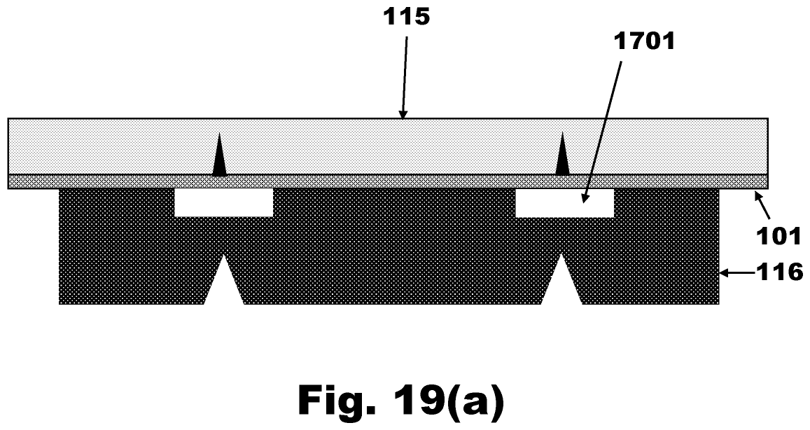

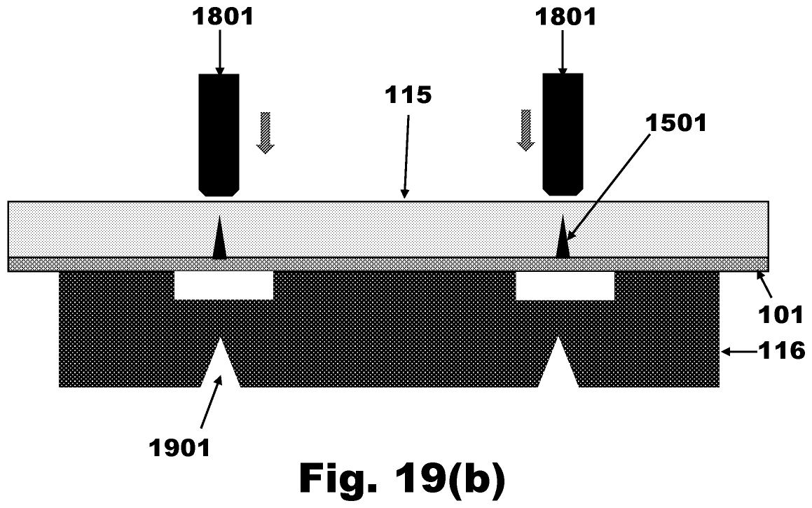

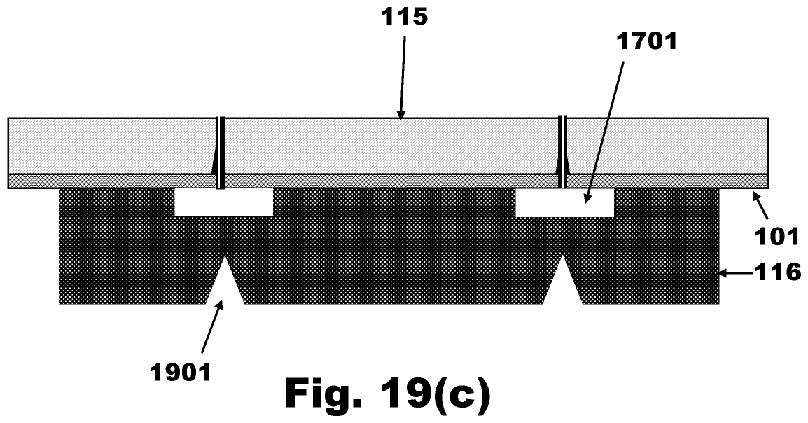

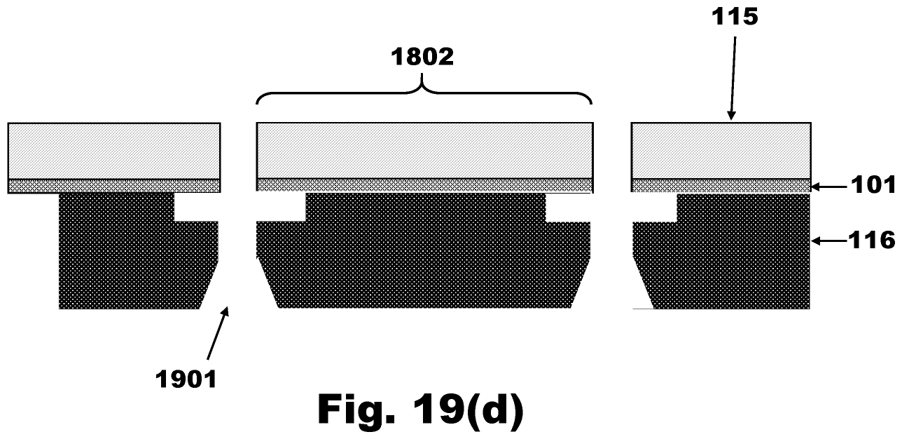

In a second method, the supporting plate 116 has depressed regions 1901, as shown in FIGS. 19(a) and 19(b). The portion of the bar 115 corresponding to the depressed regions 1901 of the supporting plate 116 are floating. Since these regions 1901 are floating, the bar 115 can bend when stress is applied to these regions 1901 by the collet 1801. Utilizing this phenomena makes the bar 115 cleave and/or divide, as shown in FIGS. 19(c) and 19(d). The supporting plates 116 are bonded like the dividing support regions 1501 being within the depressed region 1901, as shown in FIG. 19(a). Moreover, a separate portion 1902 is located the back side of the supporting plate 116, which is formed corresponding to the depressed region 1901. The separate portion 1902 helps divide the supporting plate 116.

The result of this method is a device unit 1802 comprised of the device with the supporting plate 116.

———Method 3———

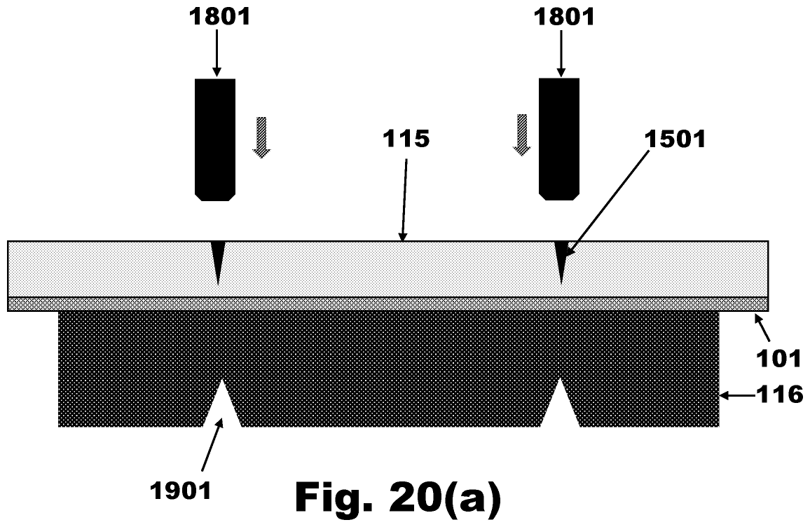

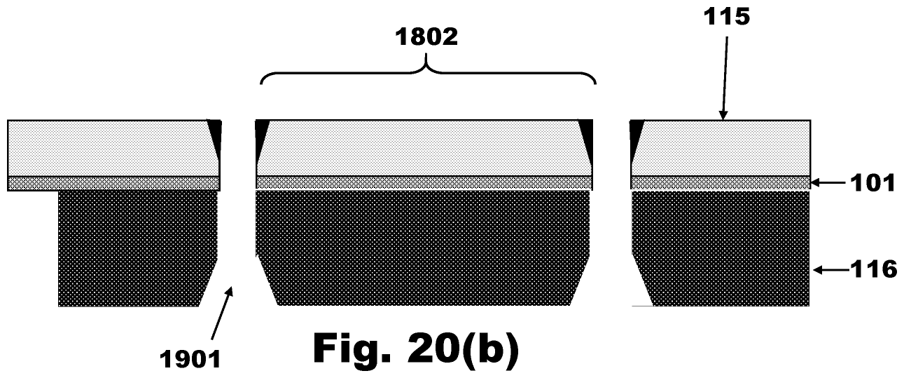

A third method is a variation on the second method without a depressed region, as shown in FIGS. 20(a) and 20(b). In this case, the supporting plate 116 and the bar 115 can be cleaved and/or divided at the same time by using the dividing support regions 1501, the separate portions 1902 and the collet 1801. By doing this, it can make the device with the supporting plate 116 as a device unit 1802.

———Method 4———

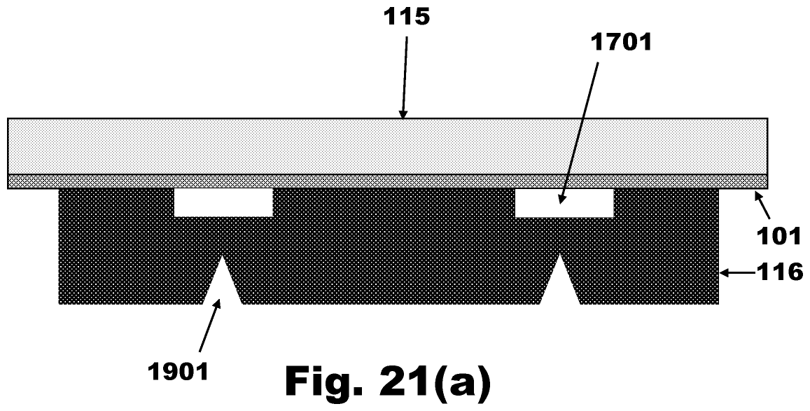

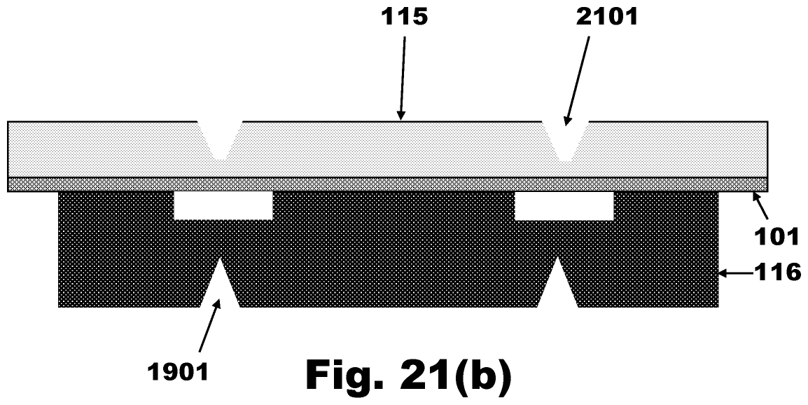

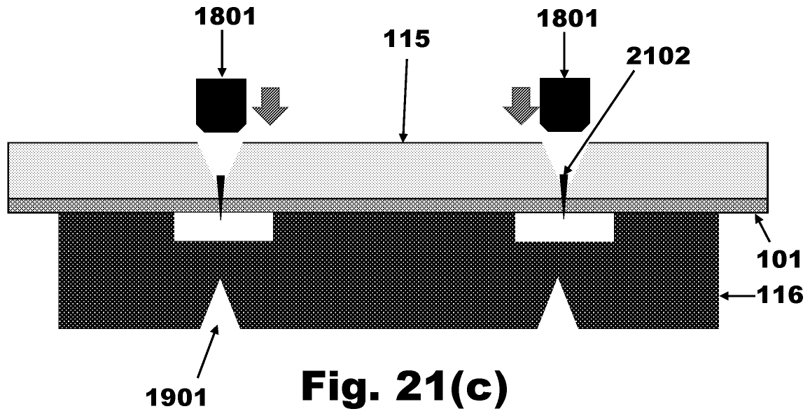

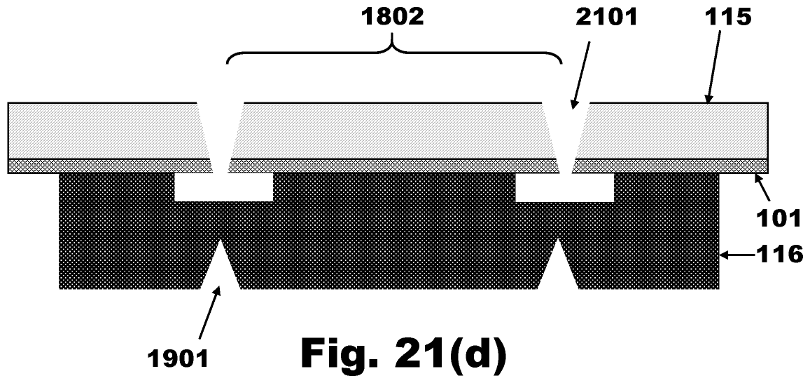

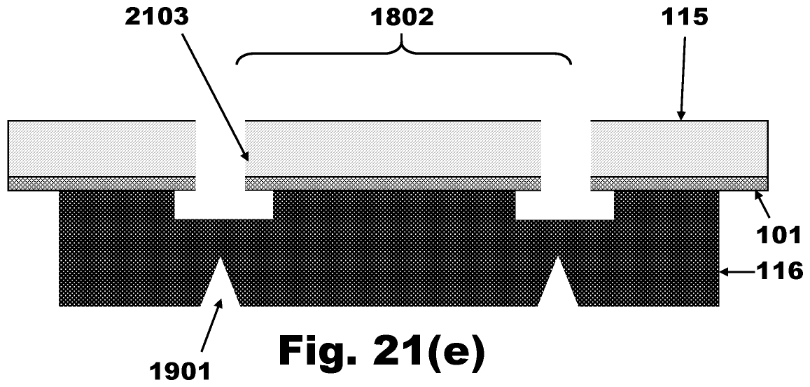

A fourth method uses a dry etch method to cleave and/or divide the bar 115, as shown in FIGS. 21(a)-21(c). The thickness of the bar 115 is the range of 5 to 100 um. The portion of the bar 115 corresponding to the depressed region 1901 is etched. However, before the etching completely separates the bar 115, the etching is stopped. Thus, the thickness of the bar 115 at an etching region 2101 is so thin that a crack 2102 appears at the etching region 2101 by an inner strain, which cleaves or divides the bar 115 automatically. If the bar 115 is not separated by this inner strain, stress can be applied to the etching region 2101 by the collet 1801, as shown in FIG. 21(c). Then, the supporting plate 116 is divided by the separate portions 1902. By doing this, it can make the device with the supporting plate 116 as a device unit 1802.

———Method 4′———

A variation on the fourth method is shown in FIGS. 21(d) and 21(e). The bar 115 is completely separated by etching at the etching portion 2101. Moreover, an etched mirror facet 2103 can be fabricated by dry etching. When making the facet 2103, the shape of facet 2103 inclines. The facet 2103 produces the desired effect in the situation where the facet 2103 is vertical to the direction of the waveguide. To realize this situation, an angle etching method can be used. The sample is placed in an etching chamber with an inclination to obtain the vertical facets 2103. This method is suitable for samples in which it is difficult to obtain vertical facets with a cleaving method, such as the semi-polar planes (20-21), (20-2-1), (30-31), (30-3-1), (11-22), etc. Then, the supporting plate 116 is separated by at the separate portion 1902. By doing this, it can make the device with the supporting plate 116 as a device unit 1802.

———Method 5———

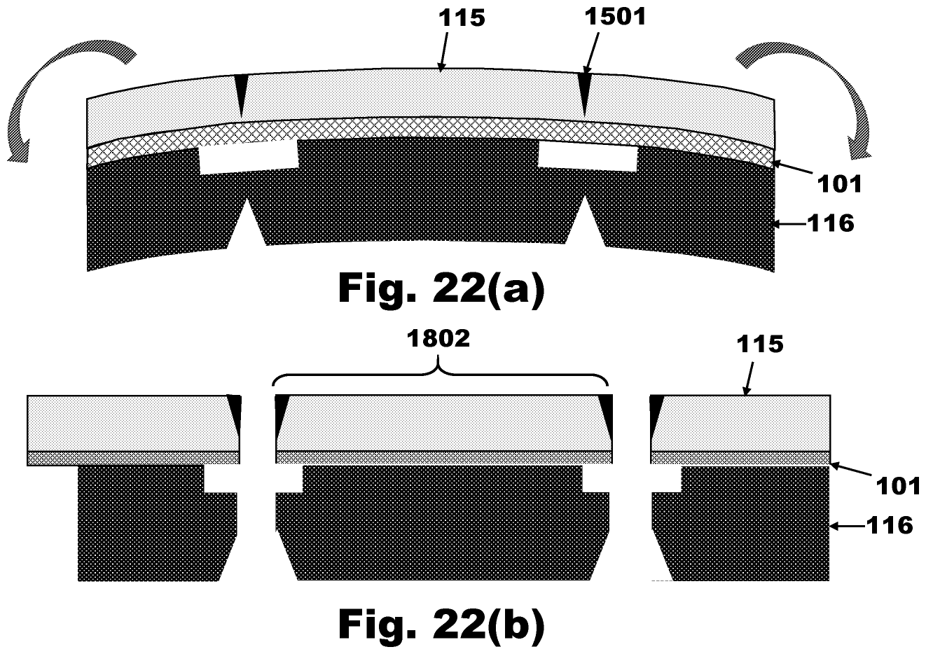

A fifth method is shown in FIGS. 22(a)-22(b). This method bends the bar 115 and supporting plate 116, which results in the bar being cleaved and/or divided. The bar 115 and supporting plate 116 are a rectangular shape with a high ratio to a short side and a long side, which therefore can easily bend. To bend the bar 115, a collet 1801 and support plate 116 can be used. Bending the bar 115 and supporting plate 116 applies stress at the dividing support region 1501. By doing this, the bar 115 and the supporting plate 116 can be cleaved and divided into the device units 1802. The direction of the bending is determined depending on the position of the dividing support region 1501. If the dividing supporting region 1501 is formed at the back side of the bar 115, as shown in FIG. 22(a), the stress applied bends the bar 115 into a convex shape.

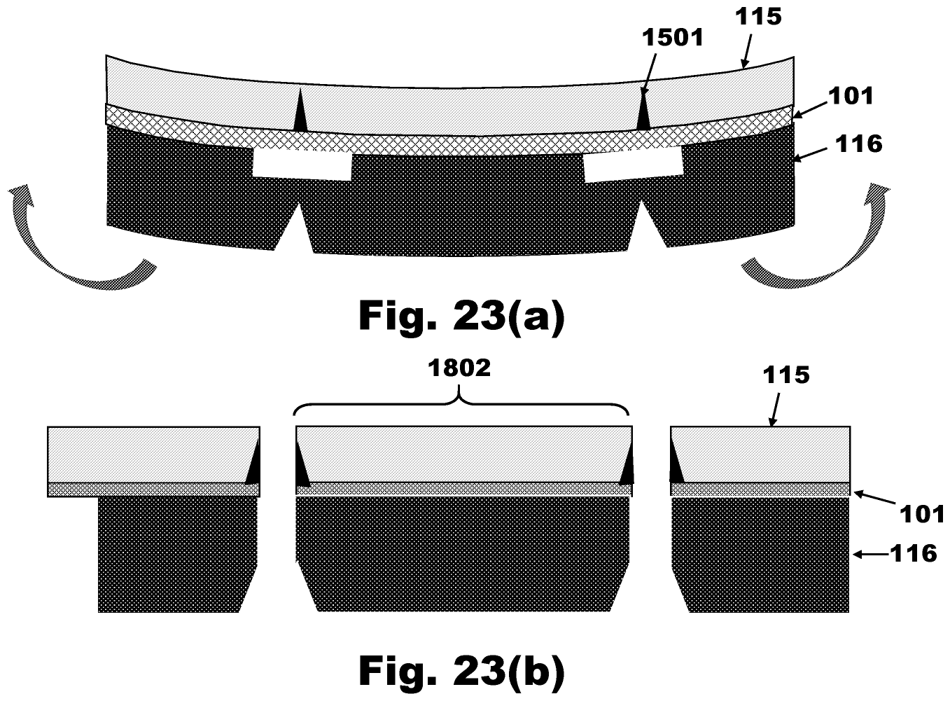

On the other hand, if the dividing supporting region 1501 is formed at the opposite side (top) of the bar 115, the stress applied bends the bar 115 into a concave shape, as shown in FIG. 23(a). By doing this, the device unit 1802 is made, as shown in FIG. 23(b).

———Method 6———

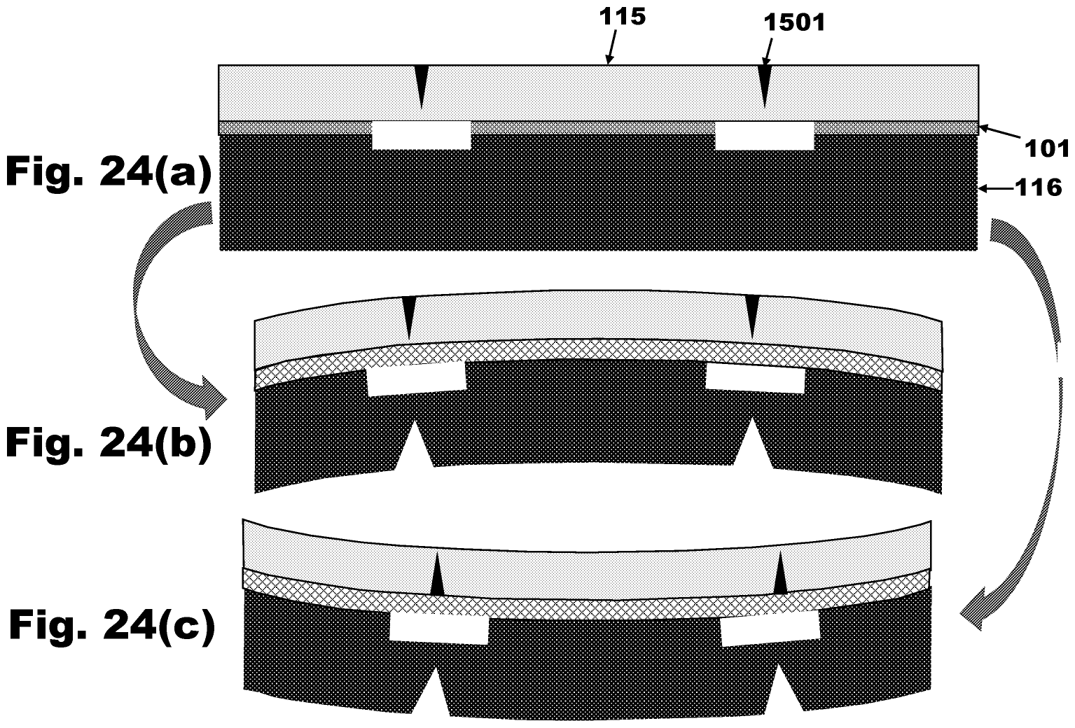

The sixth method is almost the same as the fifth method. However, the way of applying the stress is different from the fifth method. In the fifth method, the stress is applied the bar 115 mechanically by a collet 1801 and plate 116. On the other hand, in the sixth method, the stress is applied to the bar 115 using the differences in the thermal expansion co-efficient between the bar 115 and supporting plate 116, as shown in FIGS. 24(a)-24(c).

In the case of decreasing temperatures, if the thermal expansion co-efficiency of the bar 115 is larger than of the supporting plate 116, the bar 115 and supporting plate 116 become a concave shape, as shown in FIG. 24(c). On the other hand, if the thermal expansion co-efficiency of the bar 115 is smaller than of the supporting plate 116, the bar 115 and supporting plate 116 become a convex shape, as shown in FIG. 24(b). The differences in the thermal expansion co-efficiency can cleave and/or divide the bar 115 and the supporting plate 116 into the device unit 1802.

<The Edge of the Open Area>

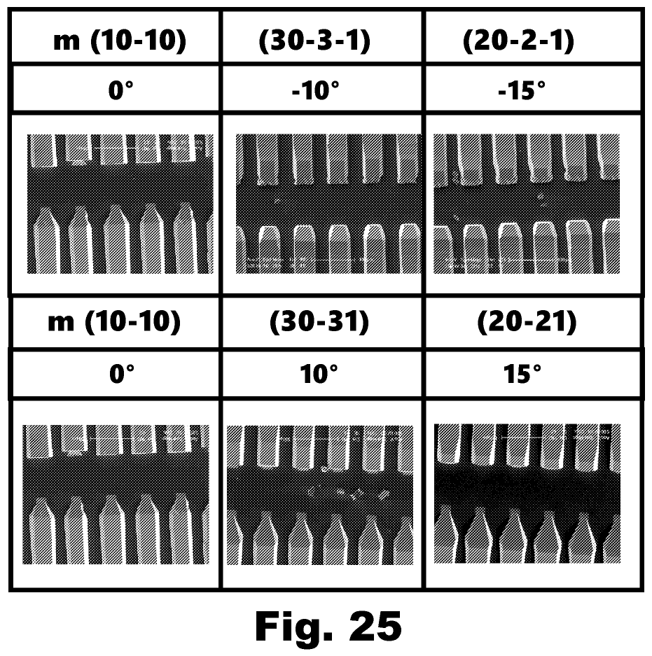

As shown in FIG. 25, after the growth of the ELO III-nitride layer 105A, the edge of the bar 115 has a variety of shapes depending on plane of the substrate 101. At the edge portion, there may be very different thicknesses of each layer of the III-nitride device layers 106 as compared to the center of the bar 115. Furthermore, both sides of the edge of the bar 115 also may have different thickness. When fabricating devices, the edge portion of the bar 115 may not be used, although the present invention can resolve this issue of different thicknesses even in this case. For example, as shown in FIGS. 18(a) 18(b), 18(c) and 18(d), the edge of the bar 115 can be eliminated easily, while simultaneously making the cleavage facet.

As another measure, using CMP is an informative method after the growth of the In-nitride ELO layers 105A. In the present invention, the ELO III-nitride layer 105A is the thickest layer among the layers in the bar 115. Thus, the difference of the thickness between the edge portion and the center portion of the bar 115 becomes larger. Therefore, after the growth of the ELO III-nitride layers 105A, the substrate 101 with the III-nitride ELO layer 105A is polished by CMP to level the surface. The III-nitride device layers 106 are not as thick as compared to the III-nitride ELO layers 105A. After the growth of the III-nitride device layers 106, the difference of the thickness between the edge portion and the center portion of the bar 115 does not cause problems when fabricating the device.

<Facet Coating Process>

The next step of device processing comprises coating the facets. While a laser diode device is lasing, the light in the device that penetrates through the facets of device to the outside of the device is absorbed by non-radiative recombination centers at the facets, so that the facet temperature increases continuously. Consequently, the temperature increase can lead to catastrophic optical damage (COD) of the facet.

A facet coating can reduce the non-radiative recombination center. To prevent COD, it is necessary to coat the facet using dielectric layers, such as AlN, AlON, Al₂O₃, SiN, SiON, SiO₂, ZrO₂, TiO₂, Ta₂O₅ and the like. Generally, the coating film is a multilayer structure comprised of the above materials. The structure and thickness of the layers is determined by a predetermined reflectivity.

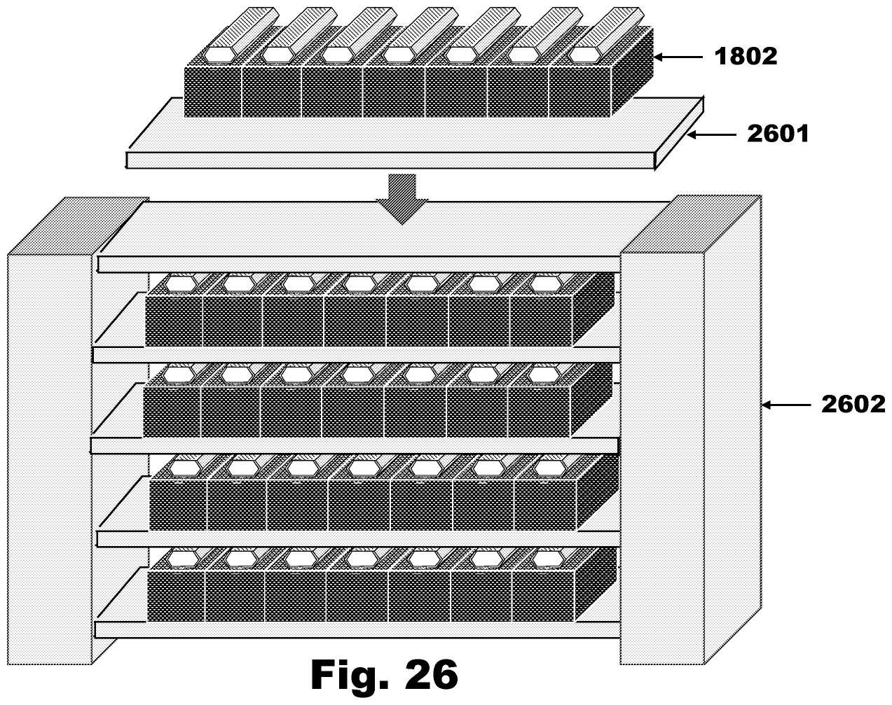

In the present invention, the bar 115 is typically divided into multiple device units 1802 to obtain the cleaving facets. The method of coating the facets needs to be performed on a number of device units 1802 at the same time in an easy manner. In facets coating process, the device units 1802 are mounted on a spacer plate 2601 in a low horizontal position before coating, as shown in FIG. 26(a). It is preferable that the spacer plate 2601 has an adhesive on its surface for the sake of fixing the device units 1802. Then, as shown in FIGS. 26(a) and 26(b), many device units 1802 are placed on a spacer plate 2601, and a plurality of spacer plates 2601 are stored in a coating holder 2602. In these processes, it is preferable to use a supporting plate 116 larger than the bar 115 in order to facilitate handling of the device units 1802, because the device units 1802 can be transferred without touching the device units 1802, thereby reducing the chance of damaging the bar 115. Note that it is not always necessary to use a spacer plate 2601, and the coating holder 2602 could be used alone.

By doing this, a number of device units 1802 can be coated simultaneously. In one embodiment, the facet coating is conducted at least two times—once for the front facet and once for the rear facet of each device unit 1802.

The length of the spacer plate 2601 is set to be almost the cavity length of the laser diode device, which makes it easy and quick to perform the coating multiple times. Once the spacer plate 2601 is set in the coating holder 2602, both facets can be coated without setting the spacer plate 2601 in the coating holder 2602 again. In one embodiment, the first coating performed on the front facet which emits the laser light, and the second coating is performed on the rear facet which reflects the laser light. The coating holder 2602 is reversed before the second coating in the facility that deposits the coating film. This reduces the lead time of the process substantially.

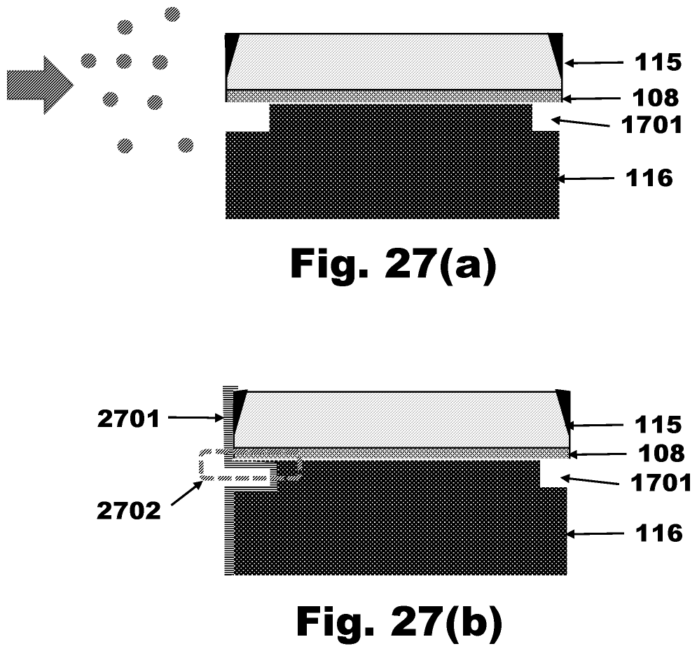

As shown in FIGS. 27(a) and 27(b), the ridge structure 108 is located at the bottom of the bar 115. When coating the facets, in the case where the supporting plate 116 has a depressed region 1701, the coating 2701 can be formed as a wrapping region 2702 at the edge of the bar 115. The existing the wrapping region helps the coating layer cover the ridge structure 108 completely, which is much preferable.

Step 6: Mount the Devices with a Supporting Plate to a Stem and Stage of a Module

In step 6, the devices with the supporting plate 116 are mounted to a stem and stage of a module, and then subjected to a screening or aging test.

Screening the Device

This step distinguishes between defective and non-defective devices. First, various characteristics of the devices are checked under a given condition; such as output power, voltage, current, resistivity, far field pattern (FFP), slope-efficiency and the like. At this point, the chips have already been mounted on a heat sink plate, so it is easy to check these characteristics.

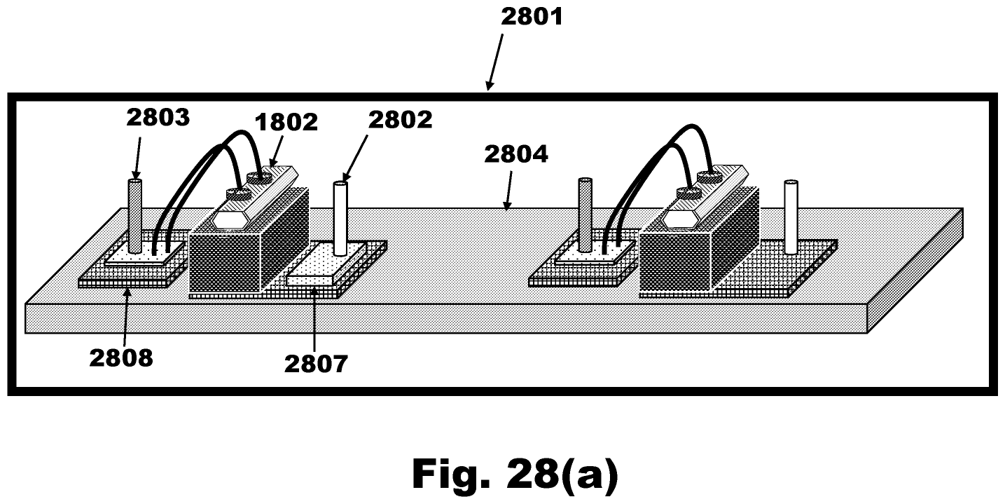

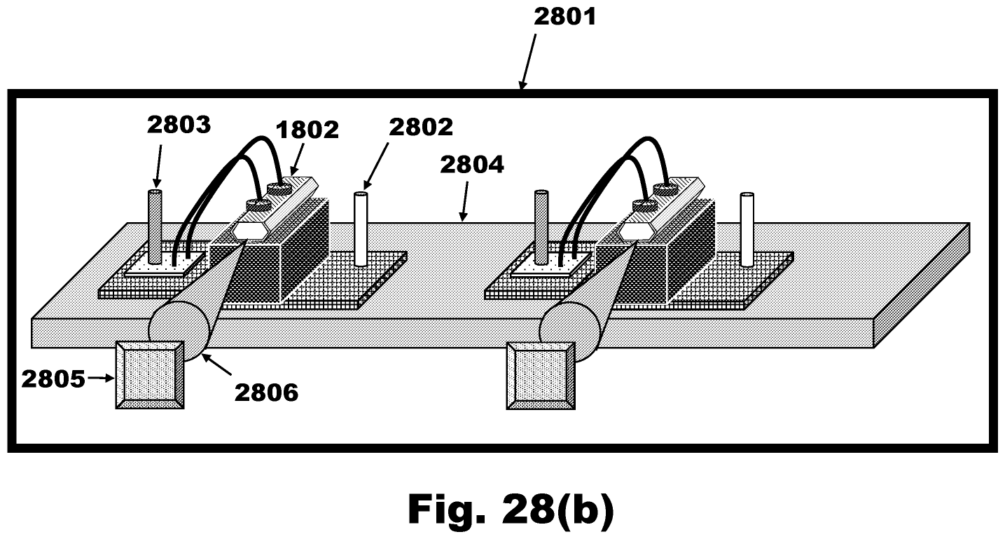

As shown in FIGS. 28(a) and 28(b), it is preferable that the aging test is conducted in a box 2801, which is sealed in dry air or nitrogen atmosphere. The p-electrode and solder, which has an electrical continuity to the n-electrode 1403, are contacted by probes 2802, 2803, respectively. Then, non-defective device units 1802 can be selected and screened by an aging test (life time test).

The heat stage 2804 maintains the temperature of the device unit 1802 with the heat sink plate during the screening test, for example, 60 degrees, 80 degrees and so on. Photodetectors 2805 are used to measure light 2806 output power, which identifies non-defective device units 1802 that have a constant output power or detects defective device units 1802.

In particularly, in the case of a III-nitride base semiconductor laser diode device, it is known that when the laser diode is oscillated in a moisture-containing atmosphere, it deteriorates. This deterioration is caused by moisture and siloxane in the air, so the III-nitride-based semiconductor laser diode needs to be sealed in dry air during the aging test. Consequently, when the III-nitride-based laser diode is shipped from a device manufacturer, the laser diode is already sealed in a dry air atmosphere.

Prior Art on the Screening or Aging Tests

Generally speaking, the screening or ageing tests are conducted before shipping, in order to screen out defective products. For example, the screening condition is conducted according to the specifications of the laser device, such as a high temperature and a high power.

Moreover, the aging test is conducted with the device mounted on/into the package, with the package sealed in dry air and/or dry nitrogen before screening. This fact makes the flexibility of packaging and mounting of the laser device restrictive.

In the prior art, if defective production happens, the defective products are discarded in the whole TO-can package, which is a great loss for production. This makes it difficult to reduce the production costs of laser diodes. There is a need to detect defective products at an earlier step.

Benefits and Advantages

The present invention method has the following advantages.

Coating the facets of the device using a heat sink plate, on which can be mounted a plurality of the devices in a low horizontal position and then, after the coating process, dividing the coated bar into the devices with a sub-mount using the trenches, allows the device with the sub-mount to be checked in the screening test in a dry air or nitrogen atmosphere.

When doing the screening test, the devices already has two contacts, namely the p-electrode and the solder on the heat sink plate, or in the case of flip-chip bonding, the n-electrode and the solder on the heat sink plate. Moreover, the present invention can select defective products using the screening test, when the device is only comprised of the chip and the sub-mount. Therefore, in the case of discarding the defective products, the present invention can reduce the loss more than the prior art, which has great value.

In the case of screening of high power laser diode devices, there are two electrode pads with solder 2807, 2808 on the heat stage 2804. One part of solder is connected to the n-electrode with a wire, another part of solder is connected to the p-electrode through a conductive supporting plate. Moreover, it is much preferable that the n-electrode are connected by two or more wires to the solder parts 2808. By doing this, the probes for applying the current to the device, which can avoid contacting the p-electrode and n-electrode directly, which, in the case of applying high current for screening of a high-power laser diode, is critical. The probes do not contact directly to the electrodes, which could break the contacted parts, in particular in the case of applying a high current density.

Mounting the Devices on or into Packages

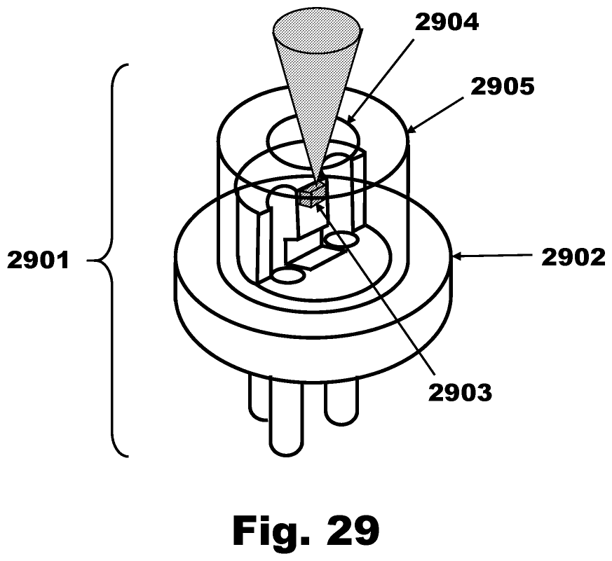

As shown in FIG. 29, a TO-can package 2901 includes a stem and stage 2902, wherein the device or chip 2903 is mounted on the stem and stage 2902. The TO-can package 2901 includes a window 2904 for the emission of light; otherwise, the TO-can package 2901 is sealed 2905.

The solder (Au—Sn, Sn—Ag—Cu and the like) or the bonding metal (Au—Au bonding), which are disposed at the bottom of the package 2901, are bonded by the wires to the solder on the package 2901, such as AlN, SIC, CuW, Cu, Al and the like. The pins of the package 2901 are connected to the solder on the plate 116 by the wires. By doing this, current from an outside supply can be applied to the device 2903.

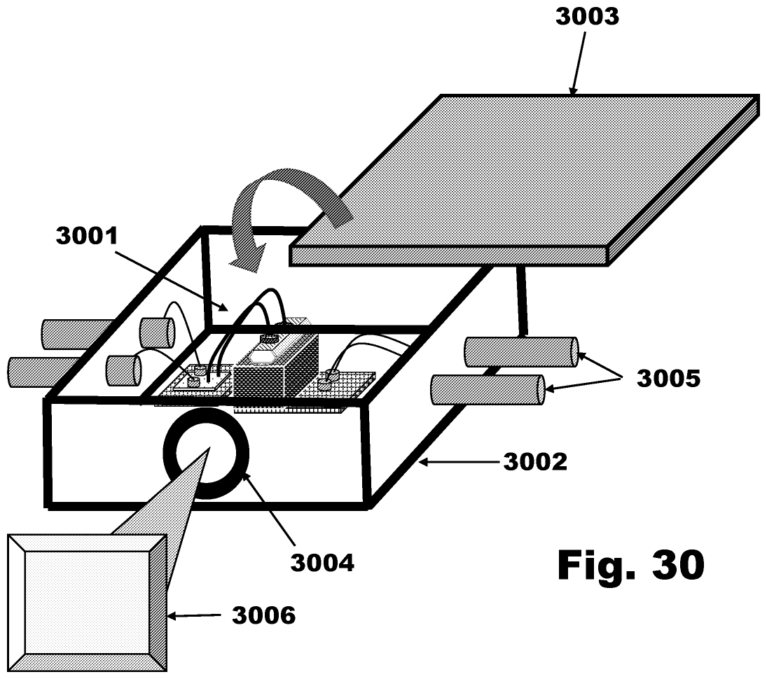

As shown in FIG. 30, the device or chip 3001 can also be mounted directly in a package 3002, which includes a lid 3003, a window 3004 for emission of light and one or more pins 3005 for electrical connections. The back side of the supporting plate 116 and the side facet of the supporting plate 116 can contact directly to the package 3002 surface. This is much preferable in terms of a heat management due to high thermal conductivity.

Furthermore, this is more preferable than solder bonding between the package 3002 and the devices 3001, which is performed by metal bonding, such as Au—Au, Au—In, etc., bonding. This method requires a flatness at the surface of package 3002 and at the back side of the devices 3001. If the supporting plate 116 is made of the silicon, it is easy to realize a surface that is atomically flat, which is preferable. Without the solder, this configuration accomplishes a high thermal conductivity and low temperature bonding, which are major advantages for the device process.

Moreover, a phosphor 3006 can be positioned outside and/or inside the package 3002. The device 3001 can be mounted in the package 3002 using various configurations because of its compact nature. Moreover, when Silicon is selected as the material of the supporting plate 116, this makes it possible to obtain a variety of shapes, sizes and surface conditions of the supporting plate 116, since silicon has a high processability. Of course, the present invention can use many types of materials, such as metals, ceramics, semiconductors, and so on.

By doing this, this module can be used as a light bulb or a head light of an automobile.

As set forth herein, these processes provide improved methods for obtaining a laser diode device, including VCSELs. In addition, once the device is removed from the substrate 101, the substrate 101 can be recycled a number of times, which accomplishes the goals of eco-friendly production and low-cost modules. These device units may be utilized as lighting devices such as light bulbs, data storage equipment, optical communications equipment such as Li-Fi, etc.

It is difficult to create a single type of package that can be used with a plurality of different types of laser diode devices. However, this method can overcome this issue by using the device units, due to being able to perform an aging test without the packaging. Therefore, it is easy to mount different types of devices in a single type of package.

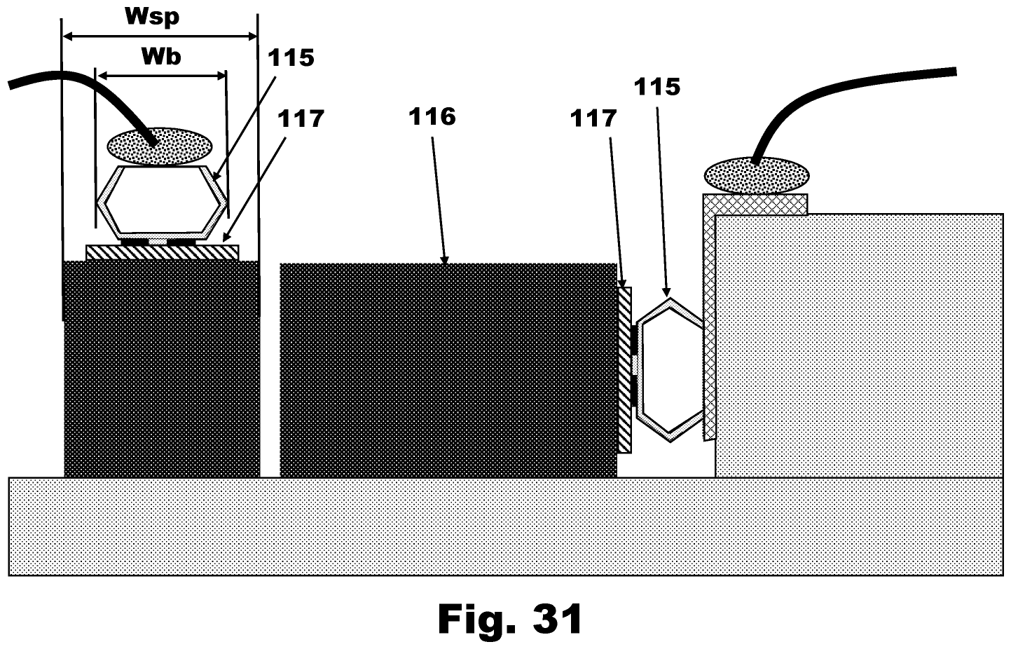

FIG. 31 illustrates the issues of handling and mounting the device units 1802. When it comes to handling a device unit 1802 and mounting to a package, the width Wb of the bar 115 is preferably narrower than the width Wsp of the supporting plate 116. When Wsp is wider than Wb, a device unit 1802 can be mounted in a manner that the side facet of the supporting plate 116 directly contacts on the surface of a package or a heat sink. If Wb is wider than Wsp, then the bar 115 prevents the side facet of the supporting plate 116 from completely contacting a package or a heat sink.

FIG. 8 illustrates the issues where the supporting plate 116 is likely to have a shape where its height Wh is larger than its width Wb. Because this shape makes it easier to remove the bar 115 from the substrate 101 by applying stress to the removing position 113 effectively.

FIG. 31 illustrates the case where the area of side facet of the supporting plate 116 is larger than the area of its bottom. In this case, utilizing the area of the side facet of the supporting plate 116 can effectively improve thermal conductivity, so it is preferable.

### Definitions of Terms

III-Nitride Substrate

As long as a III-nitride substrate 101 enables growth of a III-nitride-based semiconductor layer through a growth restrict mask 102, any GaN substrate that is sliced on a {0001}, {11-22}, {1-100}, {20-21}, {20-2-1}, {30-31}, {30-3-1}, {10-11}, {10-1-1}plane, etc., or other plane, from a bulk GaN and AlN crystal can be used.

Hetero-Substrate

Moreover, the present invention can also use a hetero-substrate 101 for the device. For example, a GaN template or other III-nitride-based semiconductor layer may be grown on a hetero-substrate 101, such as sapphire, Si, GaAs, SiC, etc., for use in the present invention. The GaN template or other III-nitride-based semiconductor layer is typically grown on the hetero-substrate 101 to a thickness of about 2-6 μm, and then the growth restrict mask 102 is disposed on the GaN template or other I-nitride-based semiconductor layer.

Growth Restrict Mask

The growth restrict mask 102 comprises a dielectric layer, such as SiO₂, SiN, SiON, Al₂O₃, AlN, AlON, MgF, ZrO₂, etc., or a refractory metal or precious metal, such as W, Mo, Ta, Nb, Rh, Ir, Ru, Os, Pt, etc. The growth restrict mask 102 may be a laminate structure selected from the above materials. It may also be a multiple-stacking layer structure chosen from the above materials.

In one embodiment, the thickness of the growth restrict mask 102 is about 0.05-3 μm. The width of the mask 102 is preferably larger than 20 μm, and more preferably, the width is larger than 40 μm. This is designed to avoid interfering adjacent supporting plates 116 to each other. The growth restrict mask 102 is deposited by sputter, electron beam evaporation, plasma-enhanced chemical vaper deposition (PECVD), ion beam deposition (IBD), etc., but is not limited to those methods.

As shown in FIGS. 3(a) and 3(b), the growth restrict mask 102 comprises a plurality of opening areas 103, which are arranged in a first direction and a second direction, periodically at intervals Wo+Wr extending in the second direction.

Typical Dimensions of the Mask

Typically, the growth restrict mask 102 used in the present invention has dimensions indicated as follows. The length of the opening area 103 is, for example, 200 to 35000 μm; the width Wo is, for example, 2 to 180 μm. In one embodiment, the growth restrict mask 102 is formed as shown in FIGS. 3(a) and 3(b) with a 1.0-μm-thick SiO₂ film, wherein the length of the opening area 102 is 4000 μm; the width Wo is 40 μm; the width of the mask is 60 μm.

Direction of the Growth Restrict Mask

On an c-plane free standing GaN substrate 101, the striped openings 103 are arranged in a first direction parallel to the 11-20 direction (a-axis) of the substrate 101 and a second direction parallel to the 10-10 direction (m-axis) of the substrate 101, periodically at a first interval and a second interval, respectively, and extend in the second direction.

On a m-plane free standing GaN substrate 101, the striped openings 103 are arranged in a first direction parallel to the 11-20 direction (a-axis) of the substrate 101 and a second direction parallel to the 0001 direction (c-axis) of the substrate 101, periodically at a first interval and a second interval, respectively, and extend in the second direction.

On a semi-polar (20-21) or (20-2-1) GaN substrate 101, the opening areas 103 are arranged in a direction parallel to [-1014] and [10-14], respectively.

Alternatively, a hetero-substrate 101 can be used. When a c-plane GaN template is grown on a c-plane sapphire substrate 101, the opening area 103 is in the same direction as the c-plane GaN template; when an m-plane GaN template is grown on an m-plane sapphire substrate 101, the opening area 103 is same direction as the m-plane GaN template. By doing this, an m-plane cleaving plane can be used for dividing the bar 115 of the device with the c-plane GaN template, and a c-plane cleaving plane can be used for dividing the bar 115 of the device with the m-plane GaN template; which is much preferable.

The width of the striped opening 103 is typically constant in the second direction, but may be changed in the second direction as necessary. It preferably be chosen the direction to be able to obtain the smooth surface easily after the growth of the III-nitride ELO layers 105A.

III-Nitride Semiconductor Layers

The III-nitride ELO layer 105A, the III-nitride regrowth layer 105B, and the III-nitride device layers 106 generally comprise (Al, In, Ga, B)N layers, and may include dopants as well as other impurities, such as Mg, Si, Zn, O, C, H, etc.

The III-nitride device layers 106 generally comprise more than two layers, including at least one layer among an n-type layer, an undoped layer and a p-type layer. The III-nitride device layers 106 specifically comprise a GaN layer, an AlGaN layer, an AlGaInN layer, an InGaN layer, etc. In the semiconductor device, a number of electrodes according to the types of the semiconductor device are disposed at predetermined positions.

Merits of Epitaxial Lateral Overgrowth

The crystallinity of the III-nitride layers 105A grown using epitaxial lateral overgrowth (ELO) upon a III-nitride substrate 101 from a striped opening 103 of the growth restrict mask 102 is very high.

Furthermore, two advantages may be obtained using a III-nitride substrate 101. One advantage is that a high-quality III-nitride ELO layer 105A can be obtained, such as with a very low defects density, as compared to using a sapphire substrate.

Another advantage in using a similar or the same material for both the epilayer and the substrate is that it can reduce strain in the epitaxial layer. Also, thanks to a similar or the same thermal expansion, the method can reduce the amount of bending of the substrate during epitaxial growth. The effect, as above, is that the production yield can be high, in order to improve the uniformity of temperature.

The use of a hetero-substrate, such as sapphire (m-plane, c-plane), LiAlO, SiC, Si, etc., for the growth of the III-nitride-based semiconductor layers is that these substrates are low-cost substrates. This is an important advantage for mass production.

When it comes to the quality of the device, the use of a free standing III-nitride substrate is much preferable, due to the above reasons. On the other hand, the use of a hetero-substrate makes it easy to remove the III-nitride-based semiconductor layers, due to a weaker bonding strength at the cleaving point.

Supporting Plates

In the present invention, there are two types of the supporting plates 116. These types of supporting plates 116 are identified type A and type B. In type A, the supporting plate 116 is predesigned to be suitable for removal of one bar 115. In type B, the supporting plate 116 has a plurality of fins, each of which corresponds to a bar 115 being removed.

Polymer Film

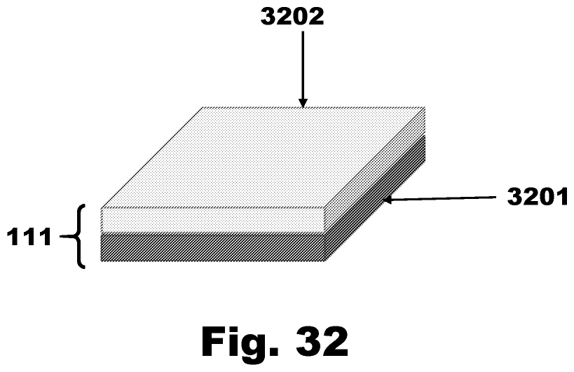

The polymer film 111 is used in order to remove the device units from a III-nitride substrate 101 or from a GaN template used with a hetero-substrate 101, as shown in FIGS. 4(i) and 4(j). In the present invention, dicing tape, including UV-sensitive dicing tape, which are commercially sold, can be used as the polymer film 111. For example, the structure of the polymer film 111 may comprise double layers, as shown in in FIG. 32, comprising a base layer 3201 and an adhesive layer 3202, but is not limited to that structure. The base film 111 material, for example, may have a thickness of about 80 μm, and may be made of polyvinyl chloride (PVC). An adhesive layer, for example, having a thickness of about 15-40 μm, may be made of acrylic UV-sensitive adhesive.

When the UV-sensitive dicing tape is exposed the UV light, the stickiness of the tape is drastically reduced. After removing the III-nitride device layers 106 from the substrate 101, the UV-sensitive dicing tape is exposed by the UV light, which makes it is easy to remove.

Devices

The semiconductor device is, for example, a Schottky diode, a light-emitting diode (LED), a laser diode (LD), a vertical cavity surface emitting laser (VCSEL), a photodiode, a transistor, sensor etc., but is not limited to these devices. This invention is particularly useful for micro-LEDs and laser diodes, such as edge-emitting lasers and vertical cavity surface-emitting lasers. This invention is especially useful for a semiconductor laser which has cleaved facets.

### ALTERNATIVE EMBODIMENTS

### First Embodiment

A I-nitride base semiconductor laser device and a method for manufacturing thereof, according to a first embodiment are explained.

In the first embodiment, as shown in FIGS. 3(a) and 3(b) and FIGS. 4(i)-4(j), a base substrate 101 is first provided, and a growth restrict mask 102 that has a plurality of striped openings areas 103 is formed on the substrate 101.

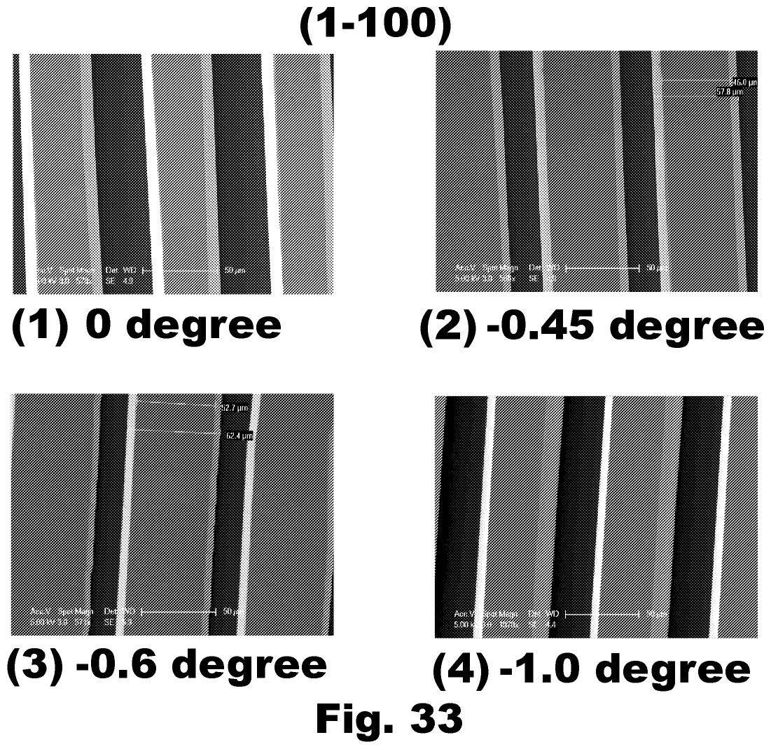

In this embodiment, the base substrate 101 is an m-plane substrate made of the ELO III-nitride-based semiconductor, which has a mis-cut orientation toward c-axis with −1.0 degree. As shown in the images of FIG. 33, the ELO III-nitride-based semiconductor layers are largely uniform with a very smooth surface.

The growth conditions of the ELO III-nitride layer can be the same MOCVD growth conditions. For example, the growth of the GaN layer is at a temperature of 950-1200° C. and a pressure of 15 kPa. For the growth of a GaN layer, trimethylgallium (TMG) and ammonia (NH₃) are used as the raw gas, and the carrier gas is only hydrogen (H₂), with silane (SiH4) as a dopant gas. The growth time is 4-8 hours.

The growth gas flow rate is following; TMG is 12 sccm, NH₃ is 8 sim, carrier gas is 3 slm, and SiH₄ is 1.0 sccm; and the V/III ratio is about 7700. This can obtain a 20 μm thick III-nitride ELO layer 105A.

After the growth of the III-nitride ELO layer 105A, the substrate 101 with the layer 105A is removed from the MOCVD equipment in order to remove the growth restrict mask 102. The growth restrict mask 102 is removed by a wet etching, using an etchant such as HF, BHF and so on. Then, the III-nitride device layers 106 can be grown on the substrate 101, as shown in FIG. 4(d). The III-nitride device layers 106 may include an InGaN layer, AlGaN layer, AlInGaN layer, AlInN layer etc.

For the growth of an AlGaN layer, triethylaluminium (TMA) is used as the raw gas; and for the growth of an InGaN layer, trimethylindium (TMI) is used as the raw gas. Under these conditions, the following layers have been grown on the III-nitride ELO layers 105A.

The ridge stripe structure, which is comprised of a p-GaN cladding layer, SiO₂ current limiting layer, and p-electrode, provides optical confinement in a horizontal direction. The width of the ridge stripe structure is of the order of 1.0 to 40 μm, and typically is 10 μm. The nitride semiconductor laser diode has the following layers, laid one on top of another in the order mentioned, on a III-nitride ELO layer (GaN layer) 105A, an InGaN/GaN 3 MQW active layer (10 nm×10 nm: 3 MQW), an AlGaN-EBL (electron blocking layer) layer, a p-GaN guiding layer, an ITO cladding layer and a p-electrode. Note that these nitride semiconductor layers may be formed of any nitride-based III-V group compound semiconductor grown in the above order.

The process for the fabrication of the device is implemented on a wafer-scale. It can use conventional methods, such as a photolithography, deposition by sputter and electron beam (EB), etching by ICP and RIE, etc. Eventually, it can obtain a diode laser structure on the substrate 101, as shown in FIG. 4(e). The bars 115 of the devices are bonded to the supporting plate 116, as shown in FIG. 4(f). The supporting plate 116 is made of silicon and uses an An—Sn solder 117. When bonding, the supporting plate 116 is heated to 250-300° C. The width Wm of the bonding metal 117 is preferably wider than the width Wp of the p-pad to which it is bonded, as shown in FIGS. 2, 9, 40, and 41. It preferable that Wm is wider than the width Wb of the bar 115 for the sake of ensuring the contact strength between the bar 115 and the supporting plate 116.

As shown in FIG. 4(g), a polymer film 111 is attached to the supporting plates 116 and stress is applied so that it enters into the space between adjacent supporting plates 116. The substrate 101 with the supporting plates 116 and polymer film 111 is cooled to utilize the different thermal expansion coefficient between the polymer film 111 and the substrate 101. Cooling the film 111 makes it shrink, which adds stress to the supporting plates 116 in a direction vertical to the bar 115. Then, it can remove the bars 115 with the supporting plates 116 from the substrate 101. The polymer film 111 has an adhesive layer to hold the supporting plates 116 after the removal of the bars 115. The adhesive layer is soft, so that the adhesive layer enters into the space of between adjacent supporting plates 116 when pressure is applied, as shown in FIGS. 4(i) and 4(j). This efficiently applies stress to the removing point 113. Moreover, the adhesive layer does not directly contact the bar 115, and thus is easy to process.

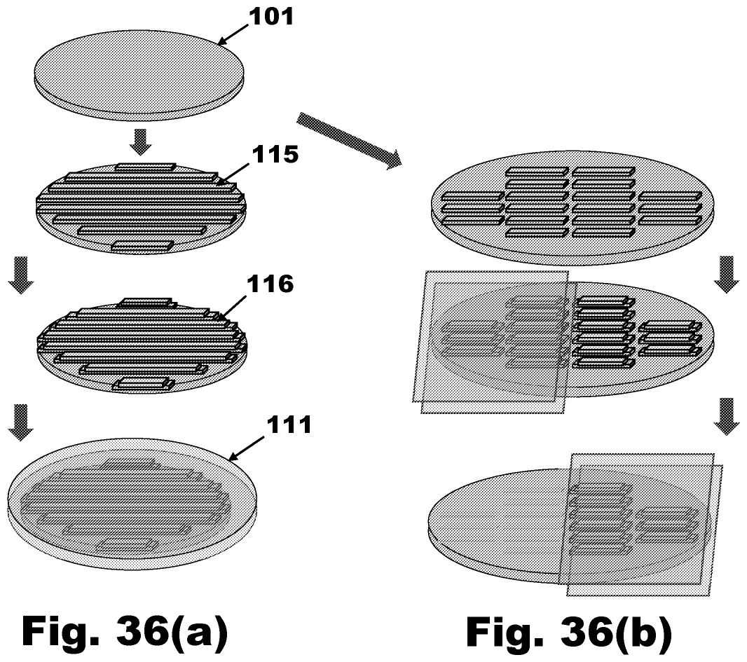

There are some options in the way of removing the bar 115, as shown in FIGS. 36(a) and 36(b). In the case of FIG. 36(a), the bars 115 extend to the edge of the substrate 101. The supporting plates 116 are then disposed on the bars 115. A polymer film 111 is attached to the supporting plates 116, covering the substrate 101 complete, and are used to remove the bar 115. In this case, it is preferable that the area of the substrate 101 can be utilized fully, with little or no space between bars 115.

In the case of FIG. 36(b) case, the bars 115 are separated onto several portions of the substrate 101. The supporting plates 116 are then disposed on the bars 115. The polymer film 111 is placed on only some of the bars 115 on the substrate 101, and only those bars 115 are removed. The remaining bars 115 on the substrate 101 can be removed by performing the same process repeatedly. This method is preferable as the wafer size of the substrate 101 increases, because the removal process can be repeated within a small area.

As shown in FIG. 14, a n-electrode 1403 which is composed of Ti/Al/Pt/Au layer may be disposed on the back side of the bar 115 using a metal mask 1402.

In this case, the cleavage facet is made using Method 2 as set forth in Step 5. First, the facet is made, then the supporting plate 116 is separated using the separate portion 1902. As shown in FIG. 26, the device units 1802 are deposited with a coating layer which is composed of an AlN/Al₂O₃ layer. Then, as shown in FIGS. 28(a) and 28(b), the screening test checks the device units 1802 for failure.

Only the device units 1802 that pass the screening test are mounted on the package, as shown in FIGS. 29 and 30. These packages are arranged as modules, which may comprise automotive headlights, light bulbs, projectors and so on.

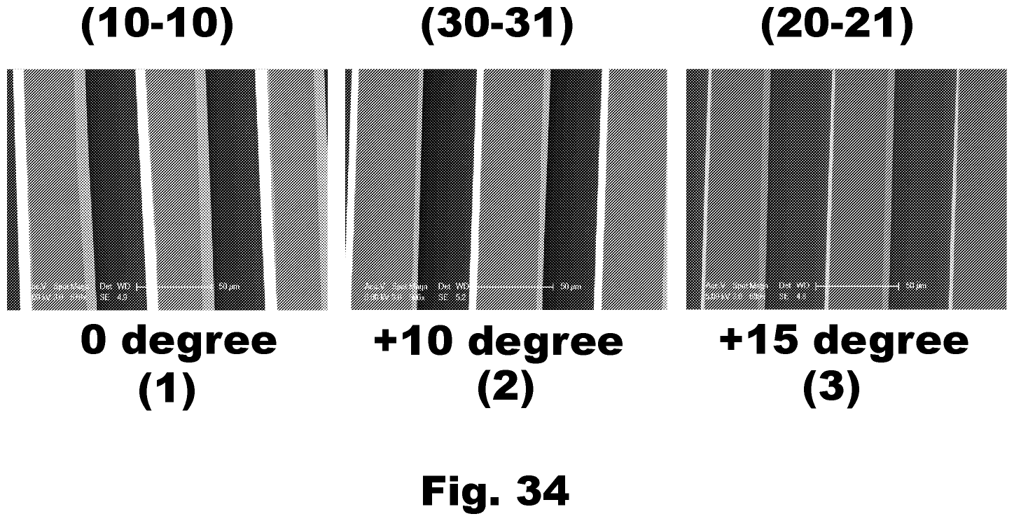

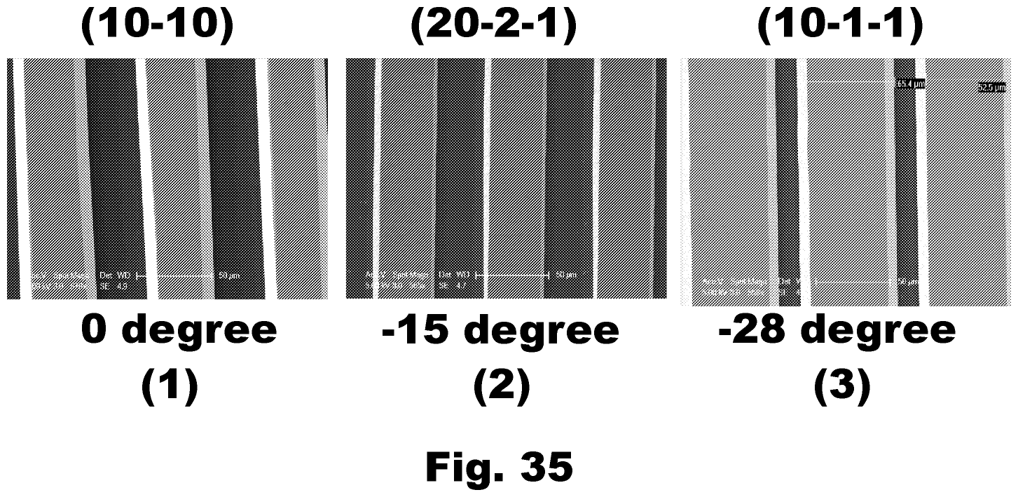

As shown in FIGS. 33, 34 and 35, the present invention can obtain a smooth surface at a variety of different planes with the ELO technique. Additionally, the present invention can obtain a smooth surface at a variety of different planes of a GaN substrate with the ELO technique. The example shown herein describes the case of an m-plane, but the present invention is not limited to those planes, and can utilize many different planes.

### Second Embodiment

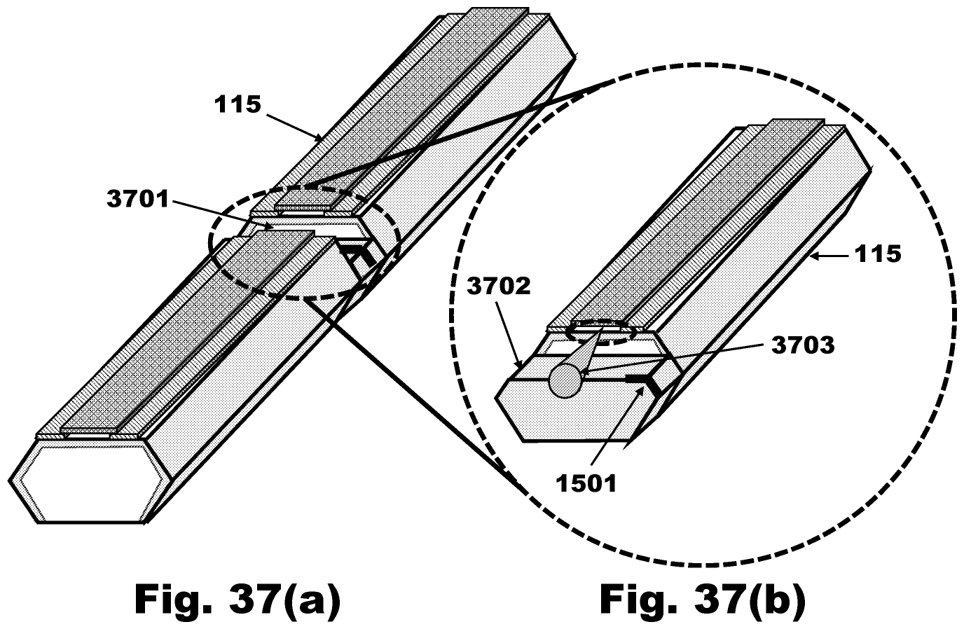

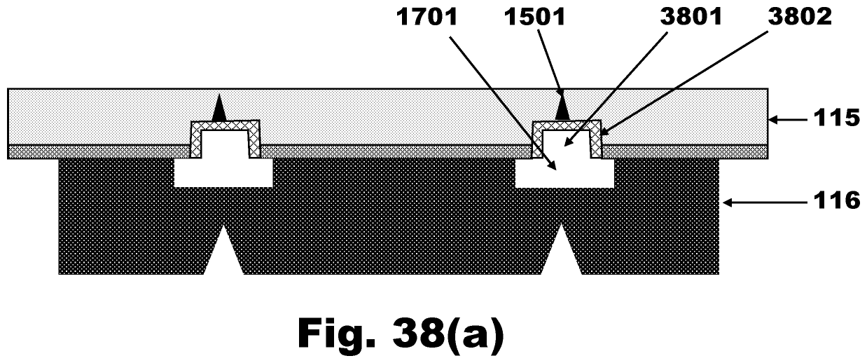

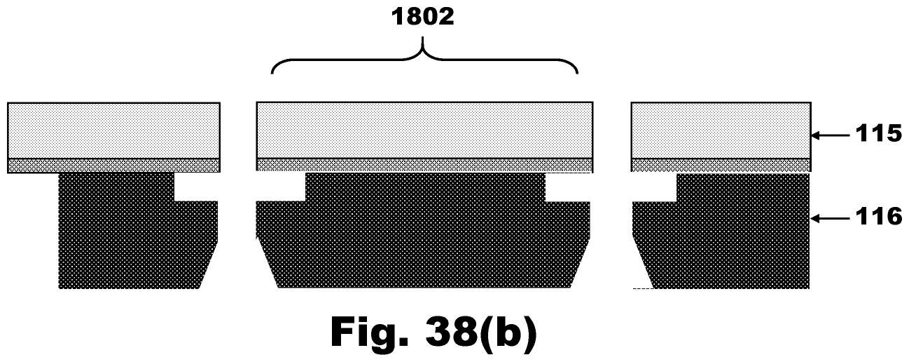

In this embodiment, the plane of the I-nitride substrate 101 is semi-polar (20-21). When using a semi-polar substrate 101, the present invention may not be able to obtain a cleavage plane at the facet of the laser diode device. In that case, a dry etching process can be used for making laser facets. As shown in FIGS. 37(a) and 37(b), etching using dry etch method results in facets 3701 and terraces 3702 on the bar 115, wherein 3703 represents light emission. Then, the dividing support region 1501 is formed on the terrace 3702, which can be utilize when dividing the bar 115 into device units 1802. FIGS. 38(a) and 38(b) further illustrate the dividing support regions 1501, depressed regions 1701, etched mirror regions 3801, and coating layers 3802. Using Method 2 of Step 5 can divide the bar 115 and the supporting plate 116 into device units 1802. By doing this, the present invention can use the semi-polar substrate 101 for edge emitting lasers. Even if using semi-polar substrates 101, the cleaving method can be used.

### Third Embodiment

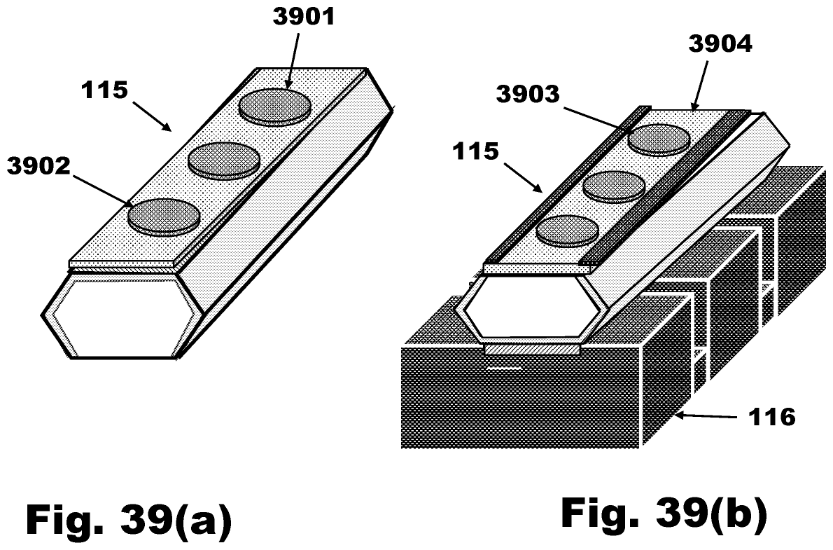

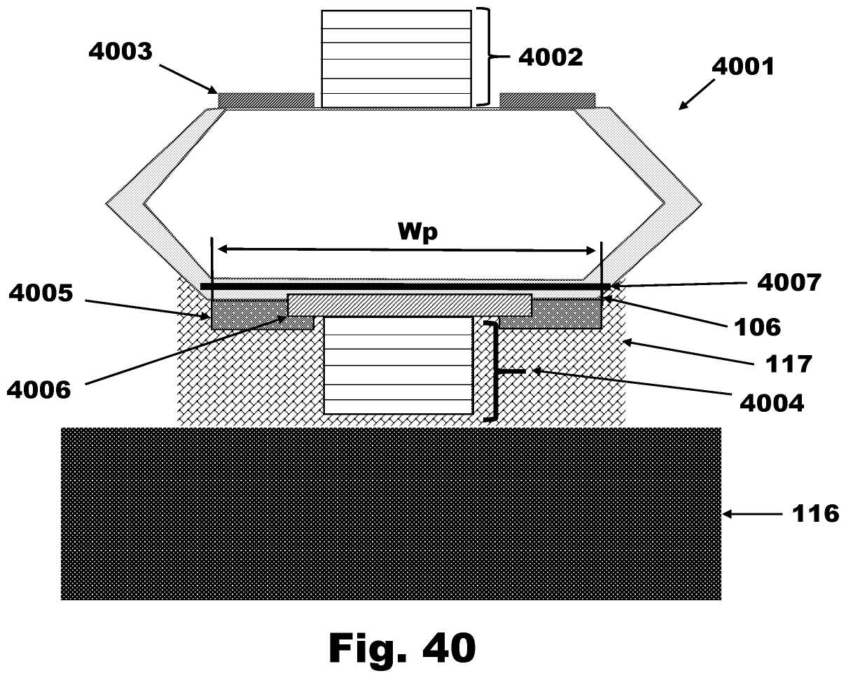

In this embodiment, the fabrication of a VCSEL is explained as shown in FIGS. 39 and 40.

FIG. 39(a) shows the structure before the removal of the bar, wherein the VCSEL structure can be conventional. A p-side DBR 3901, which is a dielectric multi-layer, such as SiO₂, Al₂O₃, TiO₂, Ta₂O₃, and p-electrode 3902 are disposed on the bar 115.

FIG. 39(b) shows the structure after removal of the bar 115 along with the supporting plate 116. An n-side DBR 3903 and n-electrode 3904 are disposed on the back side of the bar 115. In the VCSEL case, there is no need to form cleavage facets.

When dividing the bar 115 into device units, any method as set forth can be used.

FIG. 40 is a schematic of the VCSEL 4001 bonded to a supporting plate 116 using bonding metal 117, wherein the VCSEL 4001 includes an n-side DBR 4002, n-electrode 4003, p-side DBR 4004, p-electrode 4005, ITO layer 4006, and active layer 4007. Both m-plane and c-plane substrates 101 are suitable for this embodiment. After removal of the bar 115, the back side of the bar 115 is cleavage plane. Thus, the surface of the back side of the bar 115 can be very flat.

However, even if other substrates 101 are used, polishing the back side of the bar 115 by CMP, etc., makes it flat.

### Fourth Embodiment

LEDs and micro-LEDs are explained in this embodiment. The III-nitride device layers 106 are grown on the ELO III-nitride layer 105A, which is grown on a c-plane GaN substrate 101. The opening area 103, which is not depicted, is a hexagonal shape, and the diameter of the opening area is 3-250 micron meter. A high reflective p-type electrode 901 is disposed on the III-nitride device layers 106.

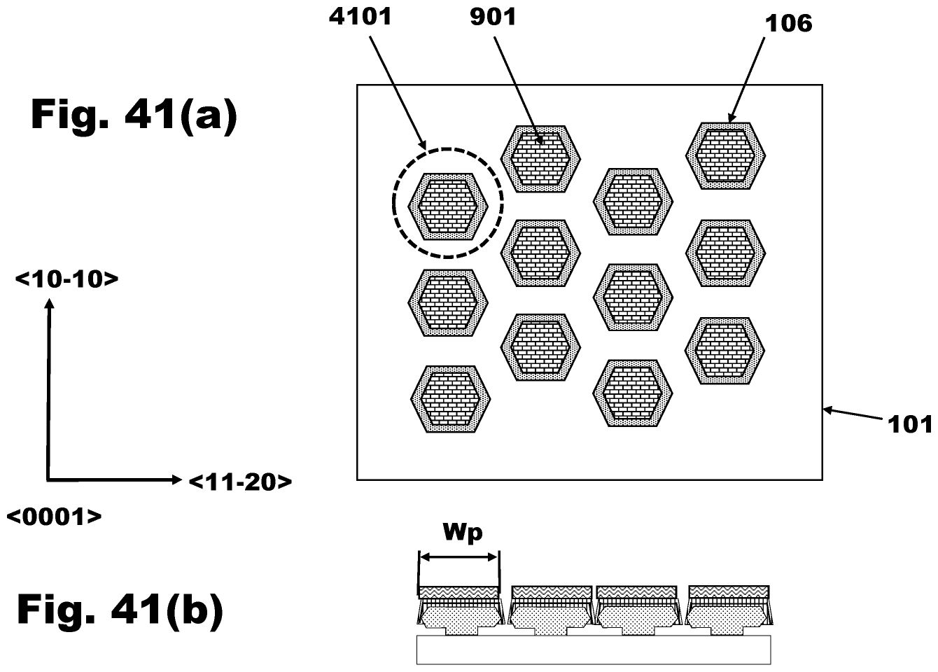

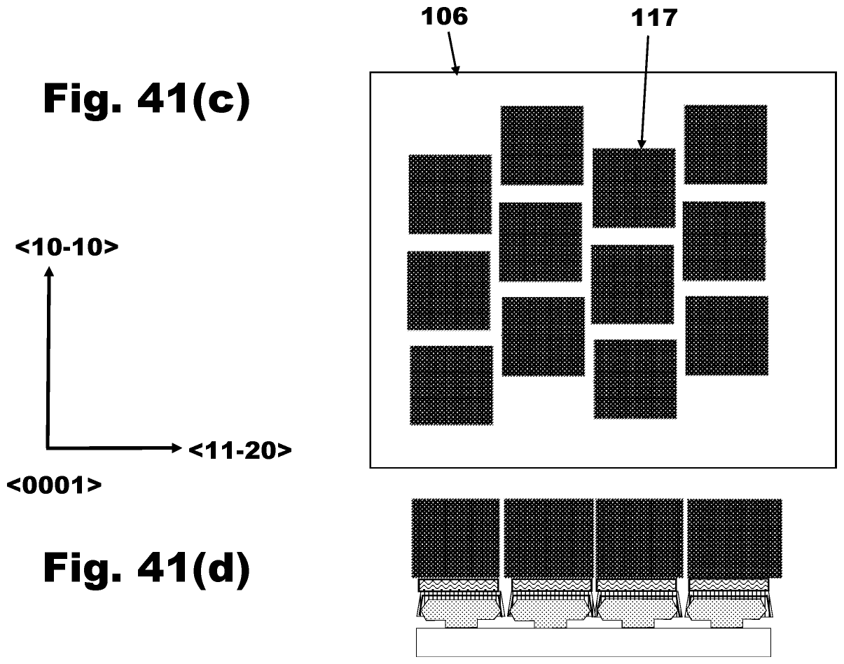

As shown in FIGS. 41(a), 41(b), 41(c) and 41(d), the supporting plate 116 is attached to the bar 4101 of the LED. In these figures, FIG. 41(a) is a first top view and FIG. 41(b) is a side view of FIG. 41(a), while FIG. 41(c) is a second top view and FIG. 41(d) is a side view of FIG. 41(c). In these embodiments, the bar 115 may not have a rectangular shape, but it is identified as a bar 115 for the convenience of the explanation regardless of the shape of the devices.

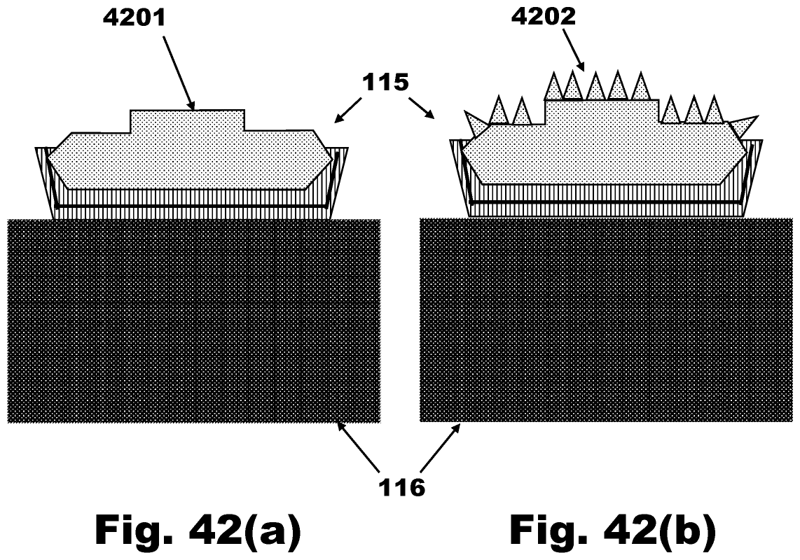

FIG. 42(a) shows the device unit after the removal of the bar 115 and supporting plate 116, wherein there is an N-polar surface 4201 at the back side of the bar 115. The N-polar surface 4201 is easy to etch with a KOH etchant, etc., which can obtain a rough surface 4202 that is suitable for light extraction, as shown in FIG. 42(b).

Eventually, the device units from this process are arranged and packaged for use.

### Fifth Embodiment

In a fifth embodiment, a sapphire substrate is used as the hetero-substrate 101. This structure is almost the same as the first embodiment, except for using the sapphire substrate 101 and a buffer layer on the sapphire substrate 101. A buffer layer is generally used with III-nitride-based semiconductor layers grown on a sapphire substrate 101. In this embodiment, the buffer layer includes both a buffer layer and n-GaN layer or undoped GaN layer. The buffer layer is grown at a low temperature of about 500-700° C. Thereafter, an n-GaN layer or undoped GaN layer is grown at a higher temperature of about 900-1200° C. The total thickness is about 1-3 μm. Then, the growth restrict mask 102 is disposed on the n-GaN layer or undoped GaN layer. The rest of process to complete the device is the same as the first embodiment, especially after the removal of the bar 115 from the sapphire substrate 101.

On the other hand, it is not necessary to use a buffer layer. For example, the growth restrict mask 102 can be disposed on the hetero-substrate directly. After that, the III-nitride ELO layer 105A, regrowth layer 105B and/or III-nitride device layers 106 can be grown. In this case, the interface between the hetero-substrate 101 surface and the bottom surface of the III-nitride ELO layer 105A can be separated easily due to the hetero-interface, which includes a lot of defects.

Employing the present invention, an atomically smooth facet for resonance can be obtained, even using a hetero-substrate 101, because the facet is formed after removing the epi-layer from the hetero-substrate 101. In this case, the type of substrate 101 does not affect the cleaving facet. On the other hand, the use of the hetero substrate 101 has a large impact for mass production.

For example, the substrate 101 used can be a low cost and large size substrate, such as sapphire, GaAs, and Si, as compared to a free-standing GaN substrate. This results in low cost devices. Moreover, sapphire and GaAs substrates are well known as low thermal conductivity materials, so devices made using these substrates have thermal problems. However, using the present invention, since the device is removed from the hetero-substrate 101, it can avoid these thermal problems.

Furthermore, in the case using the ELO growth method for removing the bar 115 of the devices, this method can drastically reduce dislocation density and stacking faults density, which has become a critical issue in the case of using hetero-substrates.

Therefore, this invention can solve many of the problems resulting from the use of hetero-substrates.

Process Steps

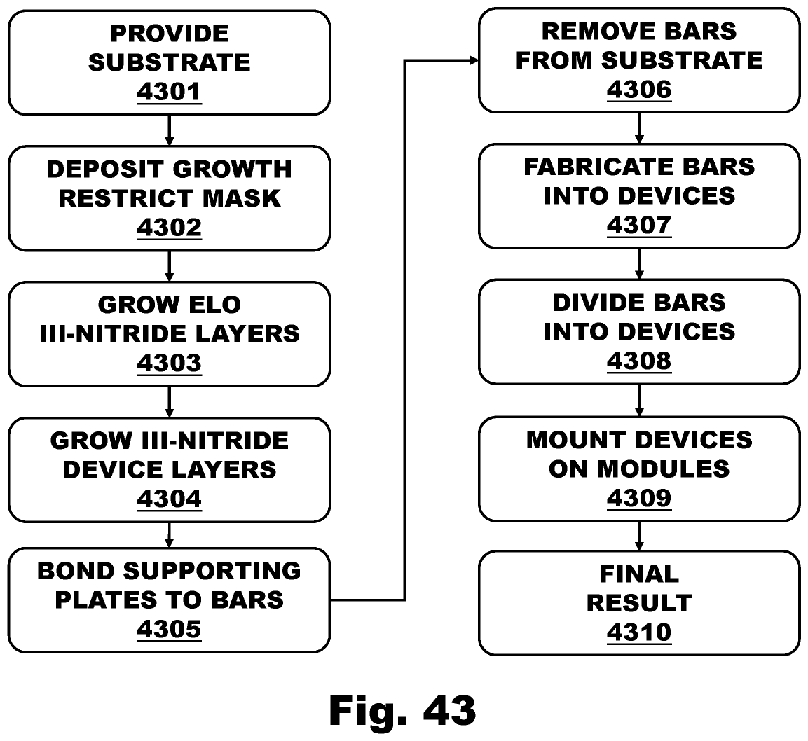

FIG. 43 is a flowchart that illustrates a method for removing a bar 115 of one or more devices from a substrate 101 using a supporting plate 116, wherein: one or more bars 115 comprised of III-nitride semiconductor layers 105A, 105B, 106 are formed on the substrate 101, and the devices' structures are formed on the bars 115; at least one supporting plate 116 is bonded to the bars 115, and stress is applied to the supporting plate 116 to remove the bars 115 from the substrate 101; the supporting plate 116 is used to make a cleavage facet for one or more of the devices' structures after the bars 115 are removed from the substrate 101; the supporting plate 116 is used to divide the bars 115 into one or more device units; and the device units are packaged and arranged into one or more modules. The steps of the method are described in more detail below.

Block 4301 represents the step of providing a base substrate 101. In one embodiment, the base substrate 101 is a III-nitride based substrate 101, such as a GaN-based substrate 101, or a hetero-substrate 101, such as a sapphire substrate 101. This step may also include an optional step of depositing a template layer on or above the substrate 101, wherein the template layer may comprise a buffer layer or an intermediate layer, such as a GaN underlayer.

Block 4302 represents the step of depositing a growth restrict mask 102 on or above the substrate 101, i.e., on the substrate 101 itself or on the template layer. The growth restrict mask 102 is patterned to include a plurality of striped opening areas 103.

Block 4303 represents the step of growing one or more III-nitride layers 105A on or above the growth restrict mask 102 using epitaxial lateral overgrowth (ELO), followed by one or more I-nitride regrowth layers 105B. This step includes stopping the growth of the ELO III-nitride layers 105A before adjacent ones of the ELO III-nitride layers 105A coalesce to each other.

Block 4304 represents the step of growing one or more III-nitride device layers 106 on or above the ELO III-nitride layer 105A and III-nitride regrowth layer 105B, thereby fabricating a bar 115 on the substrate 101. Additional device fabrication may take place before and/or after the bar 115 is removed from the substrate 101.

Block 4305 represents the step of bonding the supporting plates 116 to the bar 115. The supporting plate 116 is used to make a cleavage facet for one or more of the device structures after the bars 115 are removed from the substrate 101. The supporting plate 116 may have a width Wsp that is wider than a width Wb of the bars 115. The supporting plate 116 also may have a height Wh that is larger than a width Wb of the bars 115.

Block 4306 represents the steps of applying stress to the supporting plates 116 to remove the bar 115 from the substrate 101 at a removing position 113. This step also includes determining the removing position 113 for the bar 115. A polymer film 111 may contact the supporting plate 116 to apply the stress. The stress is applied to the supporting plates 116 orthogonal, e.g., in a vertical direction, to a surface of the bar 115 to remove the bar 115 from the substrate 101 at the removing position 113.

Block 4307 represents the step of fabricating the bars 115 into devices after the bar 115 is removed from the substrate 101.

Block 4308 represents the step of dividing the bar 115 into one or more devices by cleaving at the dividing support regions 1501 formed along the bar 115.

Block 4309 represents the step of mounting the devices with the supporting plates 116 in a module, wherein the devices are mounted to a stem and stage of the module. The supporting plates 116 may be mounted directly to the stem and stage when the supporting plates 116 have a high thermal conductivity. A side of the device may contact the stem and stage when the supporting plates 116 have a low thermal conductivity.

Block 4310 represents the resulting product of the method, namely, one or more III-nitride based semiconductor devices fabricated according to this method, as well as a substrate 101 that has been removed from the devices and is available for recycling and reuse.

The devices may comprise one or more ELO III-nitride layers 105A grown on or above a growth restrict mask 102 on a substrate 101, wherein the growth of the ELO III-nitride layers 105A is stopped before adjacent ones of the ELO III-nitride layers 105A coalesce to each other. The devices may further comprise one or more III-nitride regrowth layers 105B and one or more additional III-nitride device layers 106 grown on or above the ELO III-nitride layers 105A and the substrate 101.

Modifications and Alternatives

A number of modifications and alternatives can be made without departing from the scope of the present invention.

For example, the present invention may be used with III-nitride substrates of various orientations. Specifically, the substrates may be c-plane polar, basal nonpolar m-plane {1 0-1 0} families; and semipolar plane families that have at least two nonzero h, i, or k Miller indices and a nonzero 1 Miller index, such as the {2 0-2-1} planes. Semipolar substrates of (20-2-1) are especially useful, because of the wide area of flattened ELO growth.

In another example, the present invention is described as being used to fabricate different opto-electronic device structures, such as a light-emitting diode (LED), laser diode (LD), Schottky barrier diode (SBD), or metal-oxide-semiconductor field-effect-transistor (MOSFET). The present invention may also be used to fabricate other opto-electronic devices, such as micro-LEDs, vertical cavity surface emitting lasers (VCSELs), edge-emitting laser diodes (EELDs), and solar cells.

Benefits and Advantages

A number of benefits and advantages are derived from the present invention's method for removing devices from a substrate using supporting plates, including the following:

1. Thin layer devices having a wide width of their contact area with a substrate can be removed from the substrate.

2. Bars can be removed while avoiding breaking the bars after the removal.

3. It is easy to handle the bars after removal.

4. Bonding the supporting plates completes the process of junction-down mounting on the wafer at the same time.

5. The supporting plates can be utilized for making the facets for laser diodes.

These advantages improve yield and shorten processing times.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method, comprising:
forming one or more bars comprised of semiconductor layers on a substrate;
bonding at least one supporting plate to the bars; and
applying stress to the supporting plate to remove the bars from the substrate.

2. The method of claim 1, wherein a polymer film contacts the supporting plate to apply the stress.

3. The method of claim 1, wherein the stress is applied to the supporting plate orthogonal to a surface of the bars or in a vertical direction along a length of the bars.

4. The method of claim 1, wherein the supporting plate has a width Wsp that is wider than a width Wb of the bars.

5. The method of claim 1, wherein the supporting plate has a height Wh that is larger than a width Wb of the bars.

6. The method of claim 1, wherein the supporting plate is used to divide the bars into one or more devices after the bars are removed from the substrate.

7. The method of claim 6, wherein the devices are packaged and arranged into one or more modules.

8. The method of claim 1, further comprising forming one or more device structures on the bars.

9. The method of claim 8, wherein the supporting plate is used to make a cleavage facet for one or more of the device structures after the bars are removed from the substrate.

10. The method of claim 1, wherein at least one device or module is fabricated using the bars.

11. A method, comprising:
removing a bar of one or more devices from a substrate using one or more supporting plates, by:
fabricating the bar on the substrate;
determining a removing position for the bar;
bonding the supporting plates to the bar;
applying stress to the supporting plates to remove the bar from the substrate at the removing position;
fabricating the devices on the bar after the bar is removed from the substrate; and
mounting the devices with the supporting plates in a module.

12. The method of claim 11, wherein the stress is applied to the supporting plates orthogonal to a surface of the bar to remove the bar from the substrate at the removing position.

13. The method of claim 11, wherein the stress is applied to the supporting plates in a vertical direction to the bar to remove the bar from the substrate at the removing position.

14. The method of claim 11, wherein the devices are mounted to a stem and stage of the module.

15. The method of claim 14, wherein the supporting plates are mounted directly to the stem and stage when the supporting plates have a high thermal conductivity.

16. The method of claim 14, wherein a side of the devices contacts the stem and stage when the supporting plates have a low thermal conductivity.

17. The method of claim 14, wherein at least one of the bar, devices, or module is fabricated.

18. A method, comprising:
removing one or more devices from a substrate using a supporting plate, wherein:
one or more bars comprised of semiconductor layers are formed on a substrate, and the devices' structures are formed on the bars;
at least one supporting plate is bonded to the bars, and stress is applied to the supporting plate to remove the bars from the substrate;
the supporting plate is used to divide the bars into the devices after the bars are removed from the substrate; and
the devices are packaged and arranged into one or more modules.

19. The method of claim 18, wherein the supporting plate is used to make a cleavage facet for one or more of the devices' structures after the bars are removed from the substrate.

20. The method of claim 18, wherein at least one of the bars, devices, or modules is fabricated.
